(19) United States
(12) Patent Application Publication
(10) Pub. No.: US 2022/0052284 A1
(43) Pub. Date: Feb. 17, 2022

(54) ELECTROLUMINESCENCE ELEMENT AND DISPLAY DEVICE

(71) Applicant: SHARP KABUSHIKI KAISHA, Sakai City, Osaka (JP)

(72) Inventors: Sentaro KIDA, Sakai City, Osaka (JP); YASUSHI ASAOKA, Sakai City, Osaka (JP); JUN SAKUMA, Sakai City, Osaka (JP)

(21) Appl. No.: 17/414,114

(22) PCT Filed: Dec. 17, 2018
(86) PCT No.: PCT/JP2018/046407

§ 371 Date: Jun. 15, 2021

(51) Int. Cl. H01L 51/50; H01L 51/52; H01L 27/32

(52) U.S. Cl. CPC H01L 51/502; H01L 27/3218; H01L 51/5234; H01L 51/5218

(57) ABSTRACT

A display device according to one aspect of the disclosure includes an electroluminescence element including a light-emitting layer including quantum dots between a cathode and an anode which are paired, and further includes a platelet layer adjacent to the light-emitting layer and including plate-shaped nanoplatelets.

### TECHNICAL FIELD

The present invention relates to an electroluminescence element and a display device. The present invention relates particularly to a quantum dot light emitting diode (QLED) and a QLED display device.

### BACKGROUND ART

In recent years, a variety of flat panel displays have been developed, and in particular, a display device which includes a QLED or an organic dot light emitting diode (OLED) as an electroluminescence element has attracted attention.

PTL 1 discloses a carbonaceous material having a D/G value of greater than 0.80, a carbon nanotube, graphene, graphene oxide, or the like as an additive that can be included in a hole transport layer. PTL 2 discloses that when a charge transport material is combined with a luminescent material that is a layered material as described above, a nanosheet constituting the layered material is separated to be dispersed in the charge transport material.

### CITATION LIST

### Patent Literature

PTL 1: JP 2017-152558 A (published on Aug. 31, 2017)

PTL 2: JP 2007-088307 A (published on Apr. 5, 2007).

### SUMMARY OF INVENTION

### Technical Problem

In conventional QLEDs, there has been a problem in that a boundary between a light-emitting layer including a quantum dot (QD) and an adjacent layer thereof has irregularities and is thus blurred. As a result, the film thickness of the light-emitting layer containing the QD has been uneven, and luminance unevenness has been likely to occur.

The present invention has been made in view of the problem described above, and an object thereof is to realize an electroluminescence element and a display device in which a boundary between a light-emitting layer including a QD and an adjacent layer thereof is clear.

### Solution to Problem

An electroluminescence element according to an aspect of the present invention includes: a cathode electrode and an anode electrode which are paired; and a light-emitting layer provided between the cathode electrode and the anode electrode, the light-emitting layer including a quantum dot, and further includes a platelet layer adjacent to the light-emitting layer, the platelet layer including a nanoplatelet having a plate shape.

### Advantageous Effects of Invention

In the electroluminescence element according to an aspect of the present invention, a boundary between a light-emitting layer including a QD and an adjacent layer thereof can be made clear.

### BRIEF DESCRIPTION OF DRAWINGS

FIG. 1 is a flowchart illustrating an example of a manufacturing method of a display device according to some embodiments of the present invention.

FIG. 2 is a cross-sectional view illustrating an example of a configuration of a display region of a display device according to some embodiments of the present invention.

FIG. 3 is a cross-sectional view illustrating an example of a schematic configuration of a light-emitting element layer according to an embodiment of the present invention.

FIG. 4 is a diagram illustrating a schematic configuration of a quantum dot.

FIG. 5 is a diagram illustrating a schematic configuration of a nanoplatelet.

FIG. 6 is a diagram illustrating a schematic configuration of a nanoplatelet.

FIG. 7 is a diagram illustrating some examples of quantum dots and nanoplatelets at a boundary between a light-emitting layer and a cathode-side platelet layer.

FIG. 8 is a diagram illustrating some examples of quantum dots and nanoplatelets at the boundary between the light-emitting layer and the cathode-side platelet layer.

FIG. 9 is a diagram illustrating some examples of quantum dots and nanoplatelets at the boundary between the light-emitting layer and the cathode-side platelet layer.

FIG. 10 is a diagram illustrating some examples of quantum dots and nanoplatelets at the boundary between the light-emitting layer and the cathode-side platelet layer.

FIG. 11 is a diagram illustrating some examples of quantum dots and nanoplatelets at the boundary between the light-emitting layer and the cathode-side platelet layer.

FIG. 12 is a diagram illustrating some examples of quantum dots and nanoplatelets at the boundary between the light-emitting layer and the cathode-side platelet layer.

FIG. 13 is a diagram illustrating another example of the schematic configuration. of the light-emitting element layer according to an embodiment of the present invention.

FIG. 14 is a cross-sectional view illustrating an example of a schematic configuration of a light-emitting element layer according to a modified example of the embodiment of the present invention.

FIG. 15 is a cross-sectional view illustrating another example of the schematic configuration of the light-emitting element layer according to the modified example of the embodiment of the present invention.

FIG. 16 is a diagram illustrating an example of energy levels of HOMOs of a quantum dot composed of CdSe and ZnS, a quantum dot composed of InP and ZnS, and graphene oxide.

FIG. 17 is a cross-sectional view illustrating an example of a schematic configuration of a light-emitting element layer according to an embodiment of the present invention.

FIG. 18 is a cross-sectional view illustrating another example of the schematic, configuration of the light-emitting element layer according to an embodiment of the present invention.

FIG. 19 is a cross-sectional view illustrating an example of a schematic configuration of a light-emitting element layer according to a modified example of the embodiment of the present invention.

FIG. 20 is a cross-sectional view illustrating another example of the schematic configuration of the light-emitting element layer according to the modified example of the embodiment of the present invention.

FIG. 21 is a cross-sectional view illustrating an example of a schematic configuration of a light-emitting element layer according to a modified example of the embodiment of the present invention.

FIG. 22 is a cross-sectional view illustrating another example of the schematic configuration of the light-emitting element layer according to the modified example of the embodiment of the present invention.

FIG. 23 is a cross-sectional view illustrating an example of a schematic configuration of a light-emitting element layer according to the modified example of the embodiment of the present invention.

FIG. 24 is a cross-sectional view illustrating another example of the schematic configuration of the light-emitting element layer according to the modified example of the embodiment of the present invention.

FIG. 25 is a cross-sectional view illustrating an example of a schematic configuration of a light-emitting element layer according to an embodiment of the present invention.

FIG. 26 is a diagram illustrating an example of energy levels of HOMOs of a quantum dot composed of InP and ZnS, graphene oxide, and graphene.

FIG. 27 is a cross-sectional view illustrating an example of a method capable of manufacturing an anode-side platelet layer and an anode according to a present embodiment of the present invention.

FIG. 28 is a cross-sectional view illustrating an example of a method capable of manufacturing an anode-side platelet layer and an anode according to a present embodiment of the present invention.

FIG. 29 is a cross-sectional view illustrating an example of a method capable of manufacturing an anode-side platelet layer and an anode according to an present embodiment of the present invention.

FIG. 30 is a diagram illustrating another example of the schematic configuration of the light-emitting element layer according to an embodiment of the present invention.

FIG. 31(a) is a diagram illustrating an example of energy levels of HOMOs of a quantum dot composed of InP and ZnS, graphene oxide, an intermediate oxide between graphene oxide and graphene, and graphene. FIG. 31(b) is a diagram illustrating an example of energy levels of HOMOs of a quantum dot composed of CdSe and ZnS, graphene oxide, an intermediate oxide between graphene oxide and graphene, and graphene.

FIG. 32 is a diagram illustrating an example of a schematic configuration of a light-emitting element layer according to a present embodiment.

FIG. 33 is a diagram illustrating an example of a schematic configuration of a light-emitting element layer according to a present embodiment.

### DESCRIPTION OF EMBODIMENTS

### Method of Manufacturing Display Device and Configuration

Hereinafter, “the same layer” means that the layer is formed in the same process (film formation process), “a lower layer” means that the layer is formed in an earlier process than the process in which the layer to compare is formed, and “an upper layer” means that the layer is formed in a later process than the process in which the layer to compare is formed. Furthermore, a chemical formula “X:YO” (where X and Y are element symbols different from each other) means a mixture of XO which is an oxide of X and YO which is an oxide of Y, an oxide in which Y of an oxide YO is partially substituted with X, or both. In addition, a “semiconductor” means a material having a. band gap of 10 eV or less.

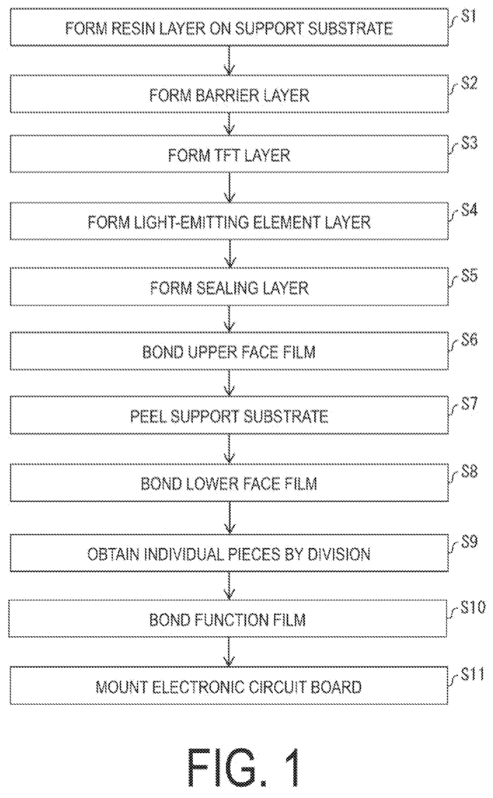

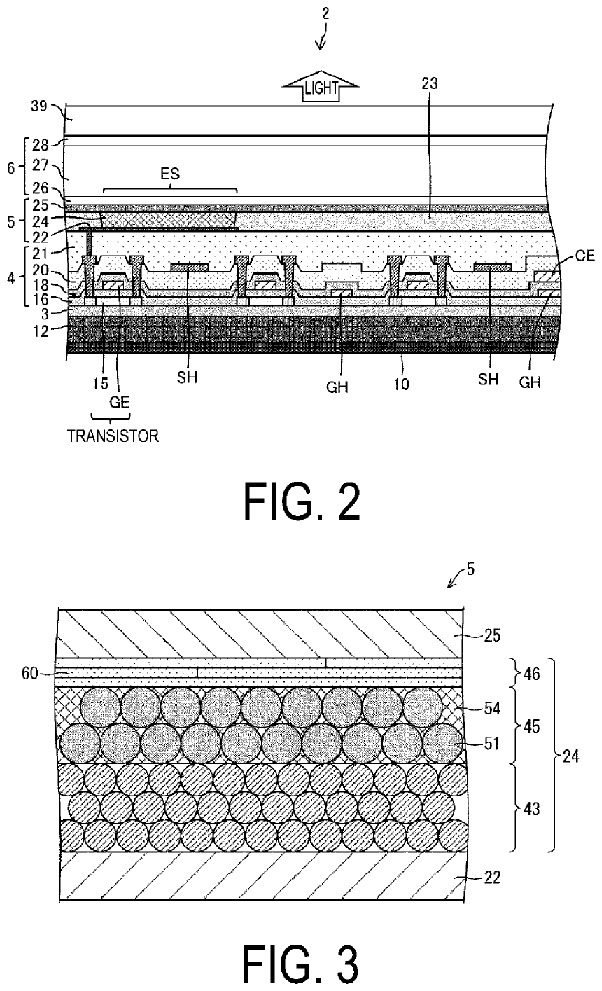

FIG. 1 is a flowchart illustrating an example of a manufacturing method of a display device. FIG. 2 is a cross-sectional view illustrating a configuration of a display region of a display device 2.

In a case where a flexible display device is manufactured, as illustrated in FIG. 1 and FIG. 2, first, a resin layer 12 is formed on a light-transmissive support substrate (a mother glass, for example) (step S1). Next, a barrier layer 3 is formed (step S2). Next, a TFT layer 4 is formed (step S3). Next, a top-emitting type light-emitting element layer 5 is formed (step S4). Next, a sealing layer 6 is formed (step S5). Next, an upper face film is bonded to the sealing layer 6 (step S6).

Next, the support substrate is peeled from the resin layer 12 due to irradiation with a laser light or the like (step S7). Next, a lower face film 10 is bonded to the lower face of the resin layer 12 (step S8). Next, the layered body including the lower face film 10, the resin layer 12, the barrier layer 3, the TFT layer 4, the light-emitting element layer 5, and the sealing layer 6 is divided to obtain a plurality of individual pieces (step S9). Next, a function film 39 is bonded on the obtained individual pieces (step S10). Next, an electronic circuit board (for example, an IC chip or an FPC) is mounted on a portion (terminal portion) of the display region located further outward (a non-display region or a frame) than a portion where a plurality of subpixels are formed (step S11). Note that steps S1 to S11 are executed by a display device manufacturing apparatus (including a film formation apparatus that executes the process from steps S1 to S5).

Examples of the material of the resin layer 12 include polyimide and the like. A portion of the resin layer 12 can be replaced by two resin films (for example, polyimide films) with an inorganic insulating film sandwiched therebetween.

The barrier layer 3 is a layer that inhibits foreign matter such as water and oxygen from entering the TFT layer 4 and the light-emitting element layer 5, and can be constituted by a silicon oxide film, a silicon nitride film, or a silicon oxynitride film, or by a layered film of these, formed by chemical vapor deposition (CVD).

The TFT layer 4 includes a semiconductor film 15, an inorganic insulating film 16 (gate insulating film) which is an upper layer above the semiconductor film 15, a gate electrode GE and a gate wiring line GH which are upper layers above the inorganic insulating film 16, an inorganic insulating film 18 which is an upper layer above the gate electrode GE and the gate wiring line GH, a capacitance electrode CE which is an upper layer above the inorganic insulating film 18, an inorganic insulating film 20 which is an upper layer above the capacitance electrode CE, a source wiring line SH which is an upper layer above the inorganic insulating film 20, and a flattening film 21 (interlayer insulating film) which is an upper layer above the source wiring line SH.

The semiconductor film 15 is constituted of, for example, a low-temperature polysilicon (LTPS) or an oxide semiconductor (for example, an In—Ga—Zn—O-based semiconductor), and a transistor (TFT) is configured to include the semiconductor film 15 and the gate electrode GE. FIG. 2 illustrates the transistor that has a top gate structure, but the transistor may have a bottom gate structure.

The gate electrode GE, the gate wiring line GH, the capacitance electrode CE, and the source wiring line SH are each composed of a single layer film or a layered film of a metal, for example, including at least one of aluminum, tungsten, molybdenum, tantalum, chromium, titanium, and copper, for example. The TFT layer 4 in FIG. 2 includes a single layer of a semiconductor layer and three layers of metal layers.

Each of the inorganic insulating films 16, 18, and 20 can be formed of, for example, a silicon oxide (SiOx) film or a silicon nitride (SiNx) film, or a layered film of these, formed by using a CVD method. The flattening film 21 can be formed of, for example, a coatable organic material such as polyimide or acrylic.

The light-emitting element layer 5 includes an anode 22 (anode electrode) which is an upper layer above the flattening film 21, an edge cover 23 having insulating properties and covering an edge of the anode 22, an active layer 24 which is an upper layer above the edge cover 23, the active layer 24 being electroluminescent (EL), and a cathode 25 (cathode electrode) which is an upper layer above the active layer 24. The edge cover 23 is formed by applying an organic material such as a polyimide or an acrylic and then patterning the organic material by photolithography, for example.

For each subpixel, a light-emitting element ES (electroluminescence element) including the anode 22 having an island shape, the active layer 24, and the cathode 25 and being a QLED is formed in the light-emitting element layer 5, and a subpixel circuit for controlling the light-emitting element ES is formed in the TFT layer 4.

For example, the active layer 24 is formed by layering a hole injection layer, a hole transport layer, a light-emitting layer, an electron transport layer, and an electron injection layer in this order, from the lower layer side. The light-emitting layer is formed into an island shape at an opening of the edge cover 23 (on a subpixel-by-subpixel basis) by vapor deposition or an ink-jet method. Other layers are formed in an island shape or a solid-like shape (common layer). A configuration is also possible in which one or more layers are not formed among the hole injection layer, the hole transport layer, the electron transport layer, and the electron injection layer.

With the light-emitting layer of the QLED, for example, an island-shaped light- emitting layer (corresponding to one subpixel) can be formed by ink-jet application a solvent having quantum dots diffused therein.

The anode 22 is a reflective electrode which is formed by layering, for example, indium tin oxide (ITO) and silver (Ag) or an alloy containing Ag, or formed from a material including Ag or Al and has light reflectivity. The cathode (cathode electrode) 25 is a transparent electrode which is constituted of a thin film of Ag, Au, Pt, Ni, or Ir, a thin film of a MgAg alloy, or a light-transmissive conductive material such as ITO, or indium zinc oxide (IZO). When the display device is not a top-emitting type display device but is a bottom-emitting type display device, the lower face film 10 and the resin layer 12 are light-transmissive, the anode 22 is a transparent electrode, and the cathode 25 is a reflective electrode.

In the light-emitting element ES, positive holes and electrons recombine inside the light-emitting layer in response to a drive current between the anode 22 and the cathode 25, and when excitons generated due to this recombination transition from the conduction band to the valence band of the quantum dots, light (fluorescence) is emitted.

The sealing layer 6 is light-transmissive, and includes an inorganic sealing film 26 for covering the cathode 25, an organic buffer film 27 which is an upper layer above the inorganic sealing film 26, and an inorganic sealing film 28 which is an upper layer above the organic buffer film 27. The sealing layer 6 covering the light-emitting element layer 5 inhibits foreign matter such as water and oxygen from penetrating the light-emitting element layer 5.

Each of the inorganic sealing film 26 and the inorganic sealing film 28 is an inorganic insulating film and can be formed of, for example, a silicon oxide film, a silicon nitride film, or a silicon oxynitride film, or a layered film of these, formed by CND. The organic buffer film 27 is a light-transmissive organic film having a flattening effect and can be formed of a coatable organic material such as an acrylic. The organic buffer film 27 can be formed, for example, by ink-jet application, and a bank for stopping droplets may be provided in the non-display region.

The lower face film 10 is, for example, a PET film bonded in a lower face of the resin layer 12 after the support substrate is peeled, to realize a display device having excellent flexibility. The function film 39 has at least one of an optical compensation function, a touch sensor function, and a protection function, for example.

A flexible display device was described above, but when a non-flexible display device is to be manufactured, ordinarily, the formation of a resin layer, and the replacement of the base material, etc. are not required, and therefore, for example, the processes of layering on a glass substrate of steps S2 to step S5 are implemented, after which the manufacturing process moves to step S9. Furthermore, when a non-flexible display device is manufactured, a light-transmissive sealing member may be caused to adhere using a sealing adhesive instead of or in addition to forming the sealing layer 6, under a nitrogen atmosphere. The light-transmissive sealing member can be formed from glass, plastic, or the like, and preferably has a concave shape.

### First Embodiment

Hereinafter, an embodiment of the present invention will be described in detail with reference to the drawings. However, shapes, dimensions, relative arrangements, and the like illustrated in the drawings are merely exemplary, and the scope of the present invention should not be construed as limiting due to these.

### Configuration of Active Layer

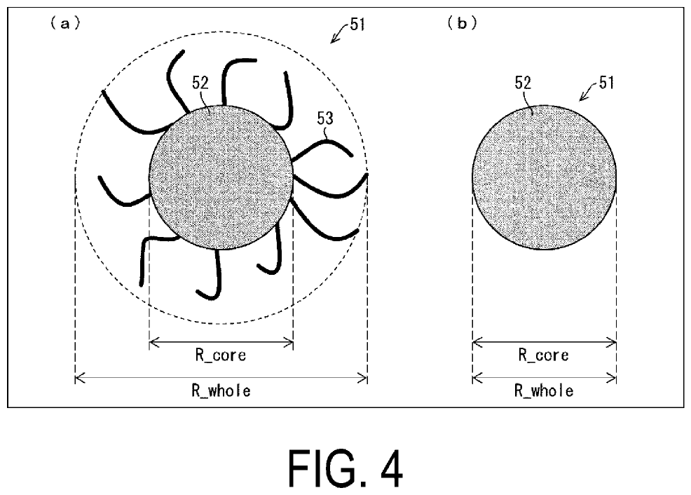

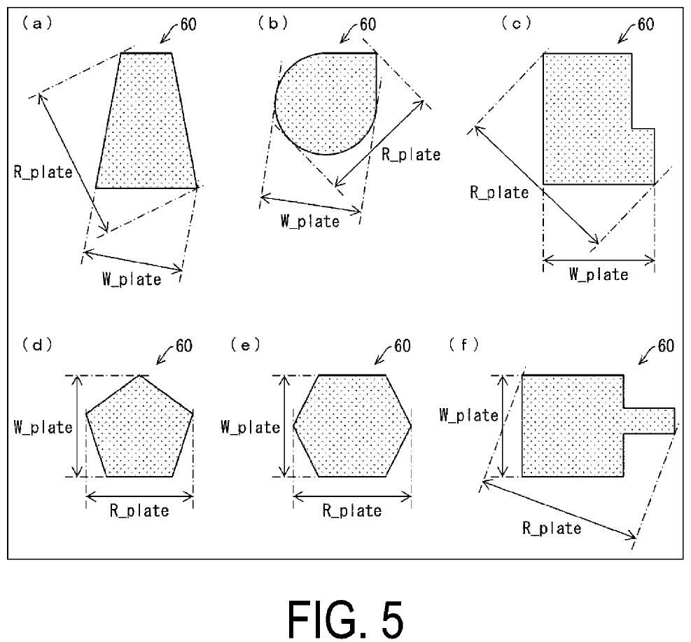

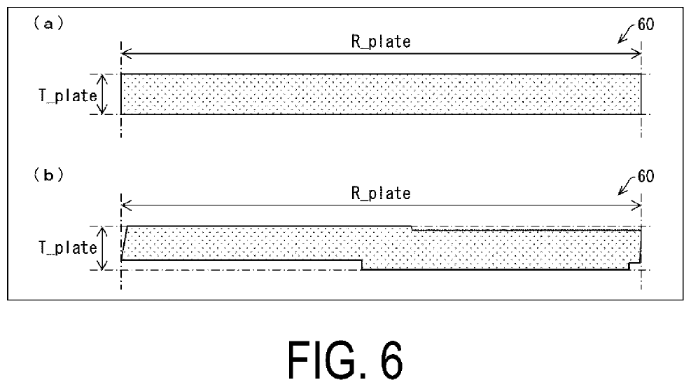

FIG. 3 is a cross-sectional view illustrating an example of a schematic configuration of a light-emitting element layer 5 according to the present embodiment. FIG. 4 is a diagram illustrating a schematic configuration of a quantum dot 51. FIG. 5 and FIG. 6 are diagrams each illustrating a schematic configuration of a nanoplatelet 60. Note that in FIGS. 3, 12 to 15, 17 to 25, 27 to 30, and 32 to 33, for convenience of illustration, nanoplatelets are illustrated in several layers, but in practice, a greater number of layers or a smaller number of layers (including a single layer) may be formed.

As illustrated in FIG. 3, an anode-side coating layer 43, a light-emitting layer 45, and a cathode-side platelet layer 46 are layered in this order on an active layer 24 of the light-emitting element layer 5 according to the present embodiment.

The anode-side coating layer 43 is formed in an upper layer above the anode 22. The anode-side coating layer 43 preferably functions as one or more of a hole injection layer, a hole transport layer, and an electron blocking layer (charge injection layer, charge transport layer, and charge blocking layer). The anode-side coating layer 43 may be formed from: undoped ZnO, Al, Cd, Cs, Cu, Ga, Gd, Ge, In, or Li; Mg-doped ZnO, TiO₂, SnO₂, WO₃, or Ta₂₃; or an inorganic material including any combination of these. Alternatively, the anode-side coating layer 43 may be formed from an organic material having electron transport properties such as: a benzene-based compound (star burst-based compound) such as 1,3,5-ris[(3-phenyl-6-tri-fluoromethyl)quinoxalin-2-yl]benzene (TPQ1), or 1,3,5-tris[{3-(4-t-butylphenyl)-6-trisfluoromethyl}quinoxalin-2-yl]benzene (TPQ2); a naphthalene-based compound such as naphthalene; a phenanthrene-based compound such as phenanthrene; a chrysene-based compound such as chrysene; a perylene-based compound such as perylene; an anthracene-based compound such as anthracene; a pyrene-based compound such as pyrene; an acridine-based compound such as acridine; a stilbene-based compound such as stilbene; a thiophene-based compound. such as BBOT; a butadiene-based compound such as butadiene:; a coumarin-based compound such as coumarin; a quinoline-based compound such as quinoline; a bis-styryl-based compound such as bis-styryl; a pyrazine-based compound such as pyrazine or distyryl pyrazine; a quinoxaline-based compound such as quinoxaline; a benzoquinone-based compound such as benzoquinone or 2,5-diphenyl-para-benzoquinone; a naphthoquinone-based compound such as naphthoquinone; an anthraquinone-based compound such as anthraquinone; an oxadiazole-based compound such as oxadiazole, 2-(4-biphenylyl)-5-(4-t-butylphenyl)-1,3,4-oxadiazole (PBD), BMD, BND, BDD, or BAPD; a triazole-based compound such as triazole, 3,4,5-triphenyl-1,2,4-triazole; an oxazole-based compound; an anthrone-based compound such as anthrone; a fluorenone-based compound such as fluorenone or 1,3,8-tritro-fluorenone (TNF); a diphenoquinone-based compound such as diphenoquinone or MBDQ, a stilbenquinone-based compound such as stilbenquinone or MBSQ; an athoraquinodimethane-based compound; a thiopyran dioxide-based compound; a fluorenylidenemethane-based compound; a diphenyldicyanoethylene-based compound; a fluorene-based compound such as fluorene, a metal or non-metal phthalocyanine-based compound such as phthalocyanine, copper phthalocyanine, or iron phthalocyanine; various metal complexes such as (8-hydroxyquinotine)aluminum (Alq3), or a complex having an oxadiazole-based polymer (polyyaxadiazole), a triazole-based polymer (polytriazole), henzoxazole, or benzothiazole as a ligand; or the like. For convenience, in the present specification, an example is given in which the anode-side coating layer 43 is a single layer, but the anode-side coating layer 43 may be a multilayer.

The light-emitting layer 45 is formed after the anode-side coating layer 43 and includes quantum dots 51. The light-emitting layer 45 may or need not include a solvent 54. The solvent 54 may volatilize when or after a material liquid is applied to form the light-emitting layer 45 as a film. The quantum dots 51 are dispersed in the solvent 54 in. the material liquid of the light-emitting layer 45. As illustrated in FIG. 4, each of the quantum dots 51 includes at least a core 52 and the core 52 is a nanocrystal (i.e., quantum dot) including a phosphor such as InP or CdSe. In addition, as illustrated in (a) of FIG. 4, in order to enhance dispersibility, the quantum dot 51 usually includes a modifying group 53 that modifies the surface of the core 52. A diameter of the quantum dot 51 herein means a diameter R_whole which includes the modifying group 53, not a diameter R_core of only the core 52 when the quantum dot 51 includes the modifying group 53 as illustrated in (a) of FIG. 4. Furthermore, when the quantum dot 51 includes no modifying group as illustrated in (b) of FIG. 4, the diameter R_whole of the quantum dot 51 corresponds to the diameter R core of only the core 52. Note that the quantum dot in the present application is discussed in terms of size unless otherwise indicated and thus, in the case of a quantum dot having a core-shell structure that is commonly used, a portion up to a shell is collectively considered as a “core” for convenience.

The diameter R_whole of the quantum dot 51 may be a design value or an average value of measured values measured using a dynamic scattering method, a transmission electron microscope (TEM), or the like. The average value may be any of an arithmetic mean value, a geometric mean value, a median value, and a mode value.

The cathode-side platelet layer 46 is formed on the light-emitting layer 45 so as to completely overlap with the light-emitting layer 45. The cathode-side platelet layer 46 is formed in an upper layer above the light-emitting layer 45 and is adjacent to the light-emitting layer 45. The cathode-side platelet layer 46 preferably functions as one or more of the electron injection layer, the electron transport layer, and the hole blocking layer. The cathode-side platelet layer 46 is a layered film in which the nanoplatelets 60 are layered and can be formed, for example, by applying a solution containing the nanoplatelets 60 onto the light-emitting layer 45 and volatilizing a solvent. An inorganic plate, an organic plate, an organic inorganic plate, a metal plate, and the like may be used for the nanoplatelet 60. Specifically, an inorganic plate obtained by forming an inorganic material such as graphene oxide, TiO₂, Ca₂NB₃O₁₀, and SnO₂ into a plate shape, an organic plate obtained by forming an organic material having electron transport properties such as a triarylamine-based compound such as NPB (N,N′-bis(2-naphthyl)-N,N′-diphenylbenzidine) or TPD (N,N′-bis(3-methylphenyl)-N,N′-diphenylbenzidine), a triarylamine-based compound such as tetracene or perylene, or a fused heterocyclic compound such as CBP (4,4′-bis(N-carbazolyl)biphenyl) into a plate shape, an organic inorganic plate obtained by forming an organic inorganic hybrid material such as (TiO₂/Ru(npm-bpy)₃)₂ into a plate shape, or a metal plate obtained by forming a metal material such as Au and Pt into a plate shape, or the like may be used. When a metal plate is used, instead of or in addition to the cathode 25, the cathode-side platelet layer 46 may function as an electrode. When graphene oxide is used, the cathode-side platelet layer 46 may function as the electron transport/injection layer, the hole blocking layer, or both.

Graphene oxide with a high purity is preferably used for the nanoplatelet 60, Specifically, graphene oxide used for the nanoplatelet 60 has a purity of preferably 50% or higher, more preferably 99% or higher, and much more preferably closer to 100%. With little impurities, it is possible to prevent a leakage and a current injection disorder caused by impurities.

When an organic plate is used for the nanoplatelet 60, the nanoplatelet 60 contains preferably 50% or more of a desired organic matter, more preferably 99% or more, and a content of the desired organic matter is even more preferably closer to 100%. The upper limit of the content of the desired organic matter is 100% based on the definition of the content. Furthermore, the desired organic matter is preferably a semiconductor such as a triarylamine-based compound such as NPB or TPD, a fused polycyclic hydrocarbon such as tetracene or perylene, or a fused heterocyclic compound such as CBP.

When an inorganic plate is used for the nanoplatelet 60, the nanoplatelet 60 contains preferably 50% or more of a desired inorganic matter, more preferably 99% or more, and a content of the desired inorganic matter is even more preferably closer to 100%. The upper limit of the content of the desired inorganic matter is 100% based on the definition of the content. Furthermore, the desired inorganic matter is preferably one of graphene oxide, graphene, and an intermediate oxide between graphene oxide and graphene or a mixture of two or more of them.

When an organic inorganic plate or a metal plate is used for the nanoplatelet 60, similarly, the content of a desired organic inorganic hybrid material or a desired metal material is preferably 50% or more, more preferably 99% or more, and even more preferably closer to 100%. The upper limit of the content of a desired machine inorganic hybrid material or the desired metal material is also 100% based on the definition of the content.

A “nanoplatelet” is a plate-shaped piece having a thickness of 0.1 nm or more and 10 nm or less, and a diameter of twice the thickness or more and 100 μm or less. The nanoplatelet 60 is usually formed by using the desired material to form a thin film and dividing or cutting the thin film. Thus, the nanoplatelet 60 is usually formed into various shapes, as illustrated in FIG. 5. The nanoplatelet 60 may have a substantially polygonal shape, a substantially circular shape, a substantially oval shape, and a shape of a combination of these in a plan view. In the present specification, a diameter R_plate and a width W_plate of the nanoplatelet 60 are geometrically defined as follows in a plan view viewed from a direction perpendicular to the widest plane of surfaces of the nanoplatelet 60. The diameter R_plate is the longest distance between a pair of parallel lines circumscribing both sides of the nanoplatelet 60 in a plan view. The width W_plate is the shortest distance between a pair of parallel lines circumscribing both sides of the nanoplatelet 60 in a plan view. Note that even if the shape of the nanoplatelet 60 is a concave polyhedron in a plan view, the diameter R_plate and the width W_plate are defined as described above.

In the present specification, a thickness T_plate of the nanoplatelet 60 is a distance between a pair of parallel planes parallel to the widest plane of the surfaces of the nanoplatelet 60 circumscribing both sides of the nanoplatelet 60, as illustrated in FIG. 6. For convenience, in the accompanying drawings, each of the nanoplatelets 60, 60a to 60n, 60′ is depicted such that the direction of the diameter R_plate is aligned in the left and right direction of each of the drawings, but the scope of the present invention is not limited to this. The direction of the diameter R_plate of each of the nanoplatelets 60, 60a to 60n, 60′ may be varied.

### Effect of Platelet Layer

When a coating layer including no nanoplatelet is formed on the light-emitting layer 45 in the prior art, the coating layer follows the quantum dots 51 included in the light-emitting layer 45 and penetrates valleys between the quantum dots 51. Such penetration of the coating layer creates irregularities at the boundary between the light-emitting layer 45 and an upper-side adjacent layer thereof, which blurs the boundary and makes the film thickness of the light-emitting layer 45 uneven. In addition, such penetration of the coating layer induces a reduction in charge injection efficiency and current concentration. As a result, luminance unevenness is likely to occur.

In contrast, the cathode-side platelet layer 46 containing the nanoplatelets 60 according to the present embodiment does not penetrate valleys between the quantum dots 51, as compared to the prior art. This is because the nanoplatelets 60 cannot follow the quantum dots 51. In this way, the penetration to valleys between the quantum dots 51 can be reduced and thus the boundary between the light-emitting layer 45 and the cathode-side platelet layer 46 has less irregularities and is clear, as compared to the prior art.

### Shape of Platelet

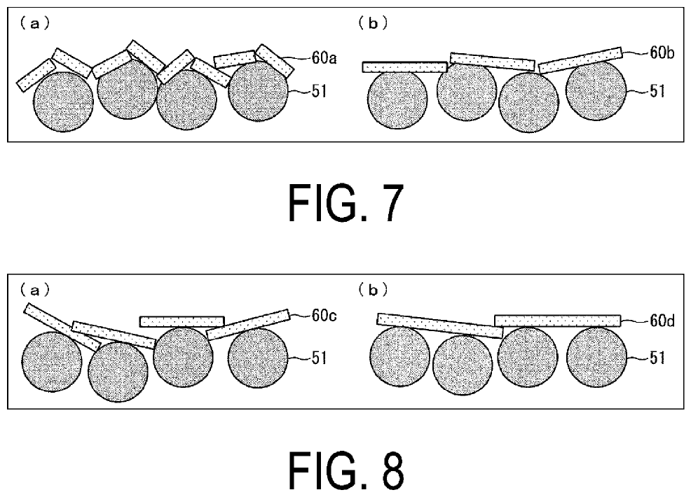

FIG. 7 is a diagram illustrating an example of the quantum dots 51 and the nanoplatelets 60a, 60b at the boundary between the light-emitting layer 45 and the cathode-side platelet layer 46. (a) of FIG. 7 illustrates the nanoplatelets 60a each having the diameter R_plate smaller than the diameter R_whole of each of the quantum dots 51, and (b) of FIG. 7 illustrates the nanoplatelets 60b each having the diameter R_plate larger than the diameter R_whole of each of the quantum dots 51. Note that for convenience, in the accompanying drawings, the nanoplatelets 60 (60a to 60n) are drawn as if they are rigid, but they are thin and thus, after the solvent is volatilized from the solution containing the nanoplatelets 60, the nanoplatelets 60 may bend along a surface shape of a lower-side adjacent layer. In addition, in FIG. 7 to FIG. 11, only a single layer is illustrated for the nanoplatelets, which is for the sake of illustration, and a plurality of layers may be actually formed.

As illustrated in FIG. 7, the nanoplatelets 60a are more likely to penetrate valleys between the quantum dots 51 than the nanoplatelets 60b. A width of each of the valleys between the quantum dots 51 corresponds to the diameter R_whole of each of the quantum dots 51 in the case of the closest packing of approximately 74% of the filling rate. Thus, the diameter R_plate of each of the nanoplatelets 60 is preferably larger than the diameter R_whole of each of the quantum dots 51.

FIG. 8 is a diagram illustrating an example of the quantum dots 51 and nanoplatelets 60c, 60d at the boundary between the light-emitting layer 45 and the cathode-side platelet layer 46, (a) of FIG. 8 illustrates the nanoplatelets 60c each having the diameter R_plate larger than once and smaller than twice the diameter R_whole of each of the quantum dots 51, and (b) of FIG. 8 illustrates the nanoplatelets 60d each having the diameter R_plate larger than twice and smaller than three times the diameter R_whole of each of the quantum dots 51.

As illustrated in FIG. 8, when the quantum dots 51 are not closely packed, the nanoplatelets 60c are more likely to penetrate valleys between the quantum dots 51 than the nanoplatelets 60d. Usually, the quantum dots 51 located on the upper face of the light-emitting layer 45 are randomly disposed at a filling rate of approximately 64%. Thus, the width of each of the valleys between the quantum dots 51 is usually larger than once and smaller than twice the diameter R_whole of each of the quantum dots 51. Thus, the diameter R_plate of each of the nanoplatelets 60 is more preferably larger than twice the diameter R_whole of each of the quantum dots 51.

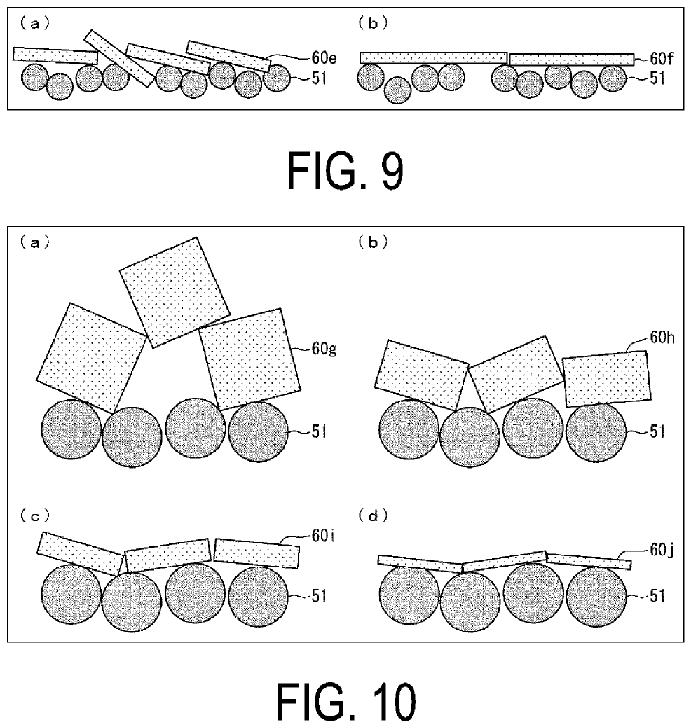

FIG. 9 is a diagram illustrating an example of the quantum dots 51 and nanoplatelets 60e, 60f at the boundary between the light-emitting layer 45 and the cathode-side platelet layer 46. (a) of FIG. 9 illustrates the nanoplatelets 60e each having the diameter R_plate larger than 3 times and smaller than 4 times the diameter R_whole of each of the quantum dots 51, and (b) of FIG. 9 illustrates the nanoplatelets 60f each having the diameter R_plate larger than 4 times and smaller than 6 times the diameter R_whole of each of the quantum dots 51.

As illustrated in FIG. 9, when the quantum dots 51 are sparsely packed, the nanoplatelets 60e are more likely to penetrate valleys between the quantum dots 51 than the nanoplatelets 60f. The quantum dots 51 located on the upper face of the light-emitting layer 45 have a filling rate of approximately 55% when sparsely packed. Thus, the width of each of the valleys between the quantum dots 51 is smaller than 3 times the diameter R_whole of the quantum dots 51 even if it is wide. Thus, the diameter R_plate of each of the nanoplatelets 60 is preferably larger than 3 times the diameter R_whole of each of the quantum dots 51. Furthermore, a valley of approximately 3 times the diameter R_whole of each of the quantum dots 51 may occur in the light-emitting layer 45 due to a film defect caused by air bubbles or the like. Thus, the diameter of each of the nanoplatelets is more preferably larger than 4 times the diameter of each of the quantum dots. In addition, the diameter R_plate is preferably 100 μm or less because a film formation failure is caused when the diameter of each of the nanoplatelets is large.

When the platelets 60 each have an elongated shape, that is, when the width W_plate is significantly smaller than the diameter R_whole, the platelets 60 easily penetrate the valleys in the direction of the width W_plate. Due to this, preferably, the platelets 60 each do not have an elongated shape. Specifically, the width W_plate is preferably larger than ½ times the diameter R_whole. In addition, the width W_plate is preferably 100 μm or less because a film formation failure is caused when the width of each of the nanoplatelets is large.

FIG. 10 is a diagram illustrating an example of the quantum dots 51 and nanoplatelets 60g to 601 at the boundary between the light-emitting layer 45 and the cathode-side platelet layer 46, (a) of FIG. 10 illustrates the nanoplatelets 60g each having the ratio of the diameter R_plate to the thickness T_plate of 1, (b) of FIG. 10 illustrates the nanoplatelets 60h each having the ratio of the diameter R_plate to the thickness T_plate of 2, and (c) of FIG. 10 illustrates the nanoplate lets 60i each having the ratio of the diameter R_plate to the thickness T_plate of 4, and (d) of FIG. 10 illustrates the nanoplatelets 60j each having the ratio of the diameter R_plate to the thickness T_plate of 8.

As illustrated in (a) of FIG. 10, when the ratio is 1, a cavity among the quantum dots 51 and the nanoplatelets 60g is quite large. Due to this, the boundary between the light-emitting layer 45 and the cathode-side platelet layer 46 ends up being blurred. On the other hand, as illustrated in (b) of FIG. 10, when the ratio is 2, a cavity among the quantum dots 51 and the nanoplatelets 60h is smaller than that when the ratio is 1. Thus, when the ratio is larger than 1, the roughness of the cathode-side platelet layer 46 is reduced (that is, smoothness is improved). In addition, the nanoplatelets 60h are more likely to deposit over the light-emitting layer 45 than the nanoplatelets 60g, such that the direction of the thickness T_plate is perpendicular. Thus, when the ratio is larger than 1, a resistivity of the cathode-side platelet layer 46 can be reduced, so that an electric conductivity between the light-emitting layer 45 and the cathode 25 can be improved. Due to this, the ratio of the diameter R_plate to the thickness T_plate is preferably larger than 1.

As illustrated in (b) of FIG. 10, when the ratio is 2, a cavity among the quantum dots 51 and the nanoplatelets 60h is smaller than that when the ratio is 1, but is large. Thus, the ratio of the diameter R_plate to the thickness T_plate is more preferably larger than 2.

Next, as illustrated in (c) and (d) of FIG. 10, when the ratio is 4, a cavity among the quantum dots 51 and the nanoplatelets 60i is smaller than that when the ratio is 2, and when the ratio is 8, a cavity among the quantum dots 51 and the nanoplatelets 60j is smaller than that when the ratio is 4, and the boundary between the light-emitting layer 45 and the cathode-side platelet layer 46 becomes more clear. In addition, as the ratio of the diameter R_plate to the thickness T_plate is larger, the nanoplatelets 60 are more likely to deposit over the light-emitting layer 45 such that the direction of the thickness T_plate is perpendicular. Thus, the ratio of the diameter R_plate to the thickness T_plate is more preferably larger than 4, and even more preferably greater than 8. In addition, the thickness T_plate is preferably 100 nm or less. This is because if the nanoplatelet layer becomes too thick when a plurality of layers are formed, roughness degradation and conductivity reduction can occur.

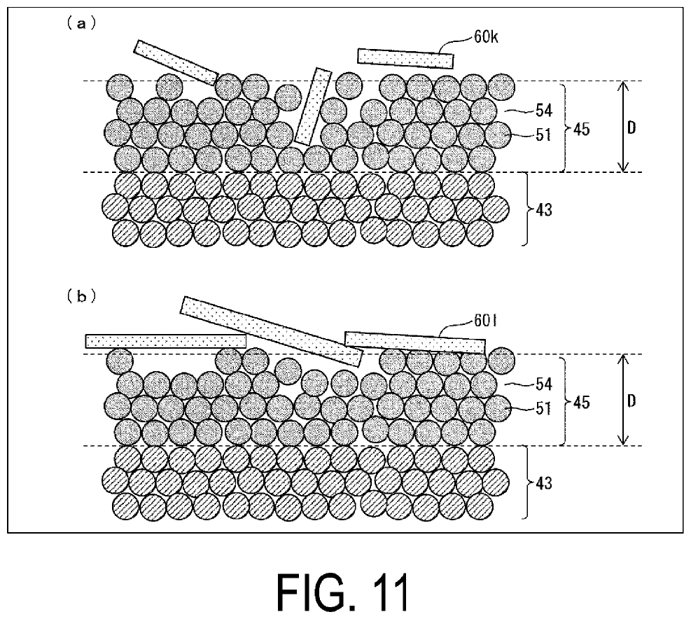

FIG. 11 is a diagram illustrating an example of the quantum dots 51 and nanoplatelets 60k, 601 at the boundary between the light-emitting layer 45 and the cathode-side platelet layer 46. (a) of FIG. 11 illustrates the nanoplatelets 60k each having the diameter R_plate smaller than the film thickness D of the light-emitting layer 45, and (b) of FIG. 11 illustrates the nanoplatelets 601 each having the diameter R_plate larger than the film thickness D of the light-emitting layer 45.

As illustrated in (a) of FIG. 11, when the diameter R_plate is smaller than the film thickness D, the nanoplatelets 60k easily sink in the light-emitting layer 45. As a result, the boundary between the light-emitting layer 45 and the cathode-side platelet layer 46 is likely to be blurred. In addition, of the nanoplatelets 60k, as for a nanoplateiet in which the direction of the thickness T_plate deviates greatly from perpendicularity to the substrate plane, a half or more of the nanoplatelet easily penetrates into the light-emitting layer 45. For convenience, when a half or more of a nanoplatelet penetrates into the light-emitting layer 45 which is a lower layer in a side view, the situation is referred to as “a nanoplatelet is buried”. Buried nanoplatelets of the nanoplatelets 60k reduce the horizontal electric conductivity of the cathode-side platelet layer 46.

In contrast, as illustrated in (b) of FIG. 11, when the diameter R_plate is larger than the film thickness D, the nanoplatelets 60k are less likely to be buried in the light-emitting layer 45. Thus, the diameter R_plate of each of the nanoplatelets 60 is preferably larger than the fihn thickness D of the light-emitting layer 45.

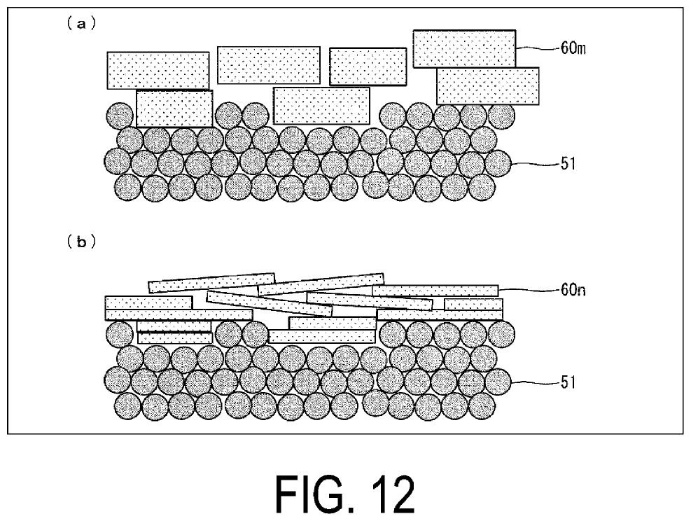

FIG. 12 is a diagram illustrating an example of the quantum dots 51 and nanoplatelets 60m, 60n at the boundary between the light-emitting layer 45 and the cathode-side platelet layer 46. (a) of FIG. 12 illustrates the nanoplatelets 60m each having the thickness T_plate larger than the diameter R_whole of each of the quantum dots 51, and (b) of FIG. 12 illustrates the nanoplatelets 60n each having the thickness T_plate smaller than the diameter R_whole of each of the quantum dots 51.

As illustrated in (a) of FIG. 12, when the thickness T_plate is larger than the diameter R_whole of each of the quantum dots 51, a cavity among (i) the quantum dots 51 and (ii) nanoplatelets stacked as the second layer of the nanoplatelets 60m stacked on the quantum dots 51 is large. As a result, the boundary between the light-emitting layer 45 and the cathode-side platelet layer 46 is blurred. In addition, the number of contact points between the quantum dots 51 and the nanoplatelets 60m is small, and thus the conductivity and the charge injection efficiency between the light-emitting layer 45 and the cathode-side platelet layer 46 are low.

In contrast, as illustrated in (b) of FIG. 12, when the thickness T_plate is smaller than the diameter R_whole of each of the quantum dots 51, a cavity among (i) the quantum dots 51 and (ii) nanoplatelets stacked as the second layer of the nanoplatelets 60n stacked on the quantum dots 51 is small. As a result, the boundary between the light-emitting layer 45 and the cathode-side platelet layer 46 becomes clear. In addition, the number of contact points between the quantum dots 51 and the nanoplatelets 60n is large, and thus the conductivity and the charge injection efficiency between the light-emitting layer 45 and the cathode-side platelet layer 46 are high. Accordingly, the thickness T_plate of each of the nanoplatelets 60 is preferably smaller than the diameter R_plate of each of the quantum dots, and specifically, it is preferably the thickness of a single molecule layer constituting the nanoplatelet itself or more and 5 nm or less. The size of a single molecule or smaller cannot be prepared, and thus the thickness is preferably 0.1 nm or more.

### First Modified Example

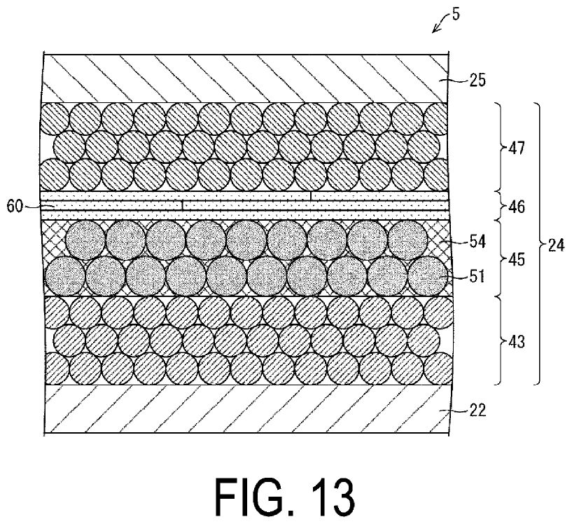

FIG. 13 is a diagram illustrating another example of the schematic configuration of the light-emitting element layer 5 according to the present embodiment.

As illustrated in FIG. 13, the active layer 24 may have a cathode-side coating layer 47 formed in an upper layer above the cathode-side platelet layer 46. The cathode-side coating layer 47 preferably functions as one or more of the electron injection layer, the electron transport layer, and the hole blocking layer. The cathode-side coating layer 47 may be formed from an inorganic material including: undoped-ZnO, Al, Cd, Cs, Cu, Ga, Gd, Ge, In, or Li; Mg-doped ZnO, TiO₂, SnO₂, WO₃, or Ta₂O₃; or any combination thereof. Alternatively, the cathode-side coating layer ₄₇ may be formed from an inorganic material including: undoped-ZnO, Al, Cd, Cs, Cu, Ga, Gd, Ge, In, or Li; Mg-doped ZnO, TiO₂, SnO₂, WO₃, or Ta₂O₃; or any combination thereof. Alternatively, the cathode-side coating layer 47 may be formed from an organic material having electron transport properties such as: a benzene-based compound (star burst-based compound) such as 1,3,5-ris[(3-phenyl-6-tri-fluoromethyl)quinoxalin-2-yl]benzene (TPQ1), or 1,3,5-tris[{3-(4-t-butylphenyl)-6-trisfluoromethyl}quinoxalin-2-yl]benzene (TPQ2); a naphthalene-based compound such as naphthalene; a phenanthrene-based compound such as phenanthrene; a chrysene-based compound such as chrysene; a perylene-based compound such as perylene; an anthracene-based compound such as anthracene; a pyrene-based compound such as pyrene; an acridine-based compound such as acridine; a stilbene-based compound such as stilbene; a thiophene-based compound such as BBOT; a butadiene-based compound such as butadiene; a coumarin-based compound such as coumarin; a quinoline-based compound such as quinoline; a bis-styryl-based compound such as his-styryl; a pyrazine-based compound such as pyrazine or distyryl pyrazine; a quinoxaline-based compound such as quinoxaline; a benzoquinone-based compound such as benzoquinone or 2,5-diphenyl-para-benzoquinone; a naphthoquinone-based compound such as naphthoquinone; an anthraquinone-based compound such as anthraquinone; an oxadiazole-based compound such as oxadiazole, 2-(4-biphenytyl)-5-(4-t-butylphenyl)-1,3,4-oxiadiazole (PBD), BMD, BND, BDD, or BAPD; a triazole-based compound such as triazole, 3,4,5-triphenyl-1,2,4-triazole; oxazole-based compound; an anthrone-based compound such as anthrone; a fluorenone-based compound such as fluorenone or 1,3,8-trinitro-fluorenone (TNF); a diphenoquinone-based compound such as diphenoquinone or MBDQ, a stilbenquinone-based compound such as stilbenquinone or MBSQ; an anthoraquinodimethane-based compound; a thiopyran dioxide-based compound; a fluorenylidenemethane-based compound; a diphenyldicyanorthytene-based compound; a fluorene-based compound such as fluorene, a metal or non-metal phthalocyanine-based compound such as phthalocyanine, copper phthalocyanine, or iron phthalocyanine; various metal complexes such as (8-hydroxyquinoline)aluminum (Alq3), or a complex having an oxadiazole-based polymer (polyoxadiazole), a triazole-based polymer (polytriazole), benzoxazole, or benzothiazole as a ligand; or the like. Although a case where the cathode-side coating layer 47 is a single layer is exemplified herein for convenience, the cathode-side coating layer 47 may have a multilayer structure.

### Second Modified Example

The anode 22, the cathode 25, and the active layer 24 therebetween may be formed in a reverse order.

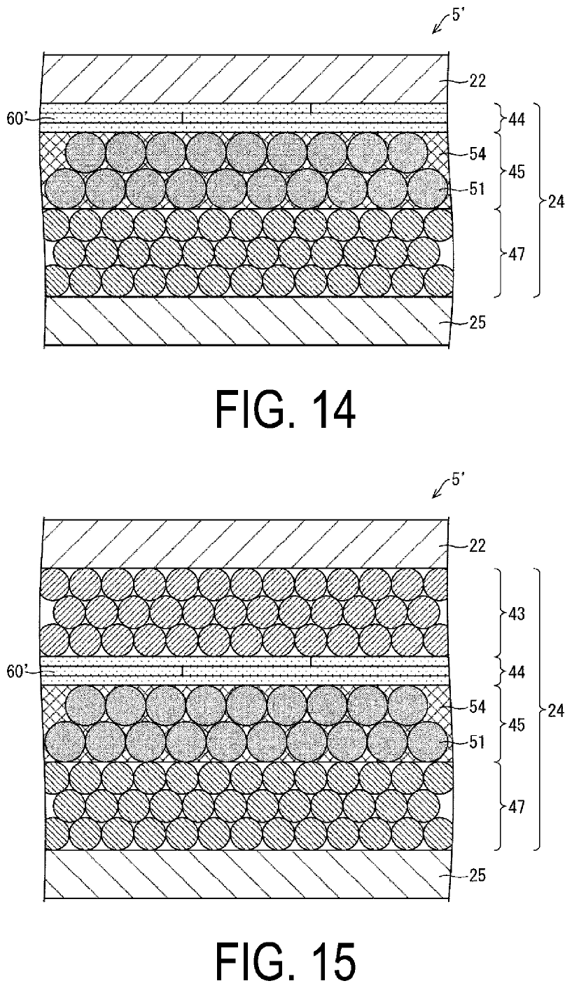

FIG. 14 is a cross-sectional view illustrating an example of a schematic configuration of a light-emitting element layer 5′ according to a modified example of the present embodiment. FIG. 15 is a cross-sectional view of another example of the schematic configuration of the light-emitting element layer 5′ according to the modified example of the present embodiment.

As illustrated in FIG. 14 and FIG. 15, in the light-emitting element layer 5′ according to the present modified example, the active layer 24 is formed in an upper layer above the cathode 25, and the anode 22 is formed in an upper layer above the active layer 24. The active layer 24 according to the present modified example includes, for example, the cathode-side coating layer 47, the light-emitting layer 45, and the anode-side platelet layer 44 in this order. In addition, in the active layer 24, the anode-side coating layer 43 may be formed in an upper layer above the anode-side platelet layer 44.

For a nanoplatelet 60′ constituting the anode-side platelet layer 44, an inorganic plate, an organic plate, an organic inorganic plate, a metal plate, or the like may be used as follows. Specifically, an inorganic plate obtained by forming an inorganic material such as graphene oxide into a plate shape; an organic plate obtained by forming an organic material having hole transport properties such as a triarylamine-based compound such as NPB or TPD, a fused polycyclic hydrocarbon such as tetracene or perylene, or a fused heterocyclic compound such as CBP into a plate shape; an organic inorganic plate obtained by forming an organic inorganic hybrid material such as (TiO₂/Ru(npm-bpy)₃)₂ into a plate shape; a metal plate obtained by forming Au and Pt metal materials into a plate shape; or the like may be used. When graphene oxide is used, the anode-side platelet layer 44 can function as the hole transport/injection layer, the electron blocking layer, or both of them.

The nanoplatelet 60′ constituting the anode-side platelet layer 44 preferably has a diameter R_plate larger than the diameter R_whole of each of the quantum dots 51, more preferably has a diameter R_plate larger than twice the diameter R_whole, and even more preferably has a diameter R_plate larger than four times the diameter R_whole, to the nanoplatelet 60 constituting the cathode-side platelet layer 46. Preferably, the width W plate is larger than ½ times the diameter R_whole. The ratio of the diameter R_plate to the thickness T_plate is preferably larger than 1, more preferably larger than 2, even more preferably larger than 4, and still even more preferably larger than 8. The diameter R_plate is preferably larger than the film thickness D of the light-emitting layer 45. The thickness T_plate is preferably smaller than the diameter R_plate of each of the quantum dots, and specifically, the thickness T_plate is preferably the thickness of a single molecule layer constituting the nanoplatelet 60′ itself or more and 5 nm or less, The size of a single molecule or smaller cannot be prepared, and thus the thickness is preferably 0.1 nm or more,

The light-emitting element ES including the light-emitting element layer 5′ according to the present modified example may be of a bottom-emitting type or a top-emitting type. In a case of the bottom-emitting type, for example, the anode 22 is formed by layering of indium tin oxide (ITO) and silver (Ag) or an alloy containing Ag, or is a reflective electrode formed from a material including Ag or Al and having light reflectivity. In a case of the bottom-emitting type, the cathode (cathode electrode) 25 is a thin film of Ag, a thin film of a MgAg alloy, or a transparent electrode constituted by a light-transmissive conductive material such as ITO or indium zinc oxide (IZO). In a case of the top-emitting type, the anode 22 is a transparent electrode and the cathode 25 is a reflective electrode. The transparent electrode is capable of transmitting light emitted from the light-emitting layer 45, and the reflective electrode is capable of reflecting light emitted from the light-emitting layer 45.

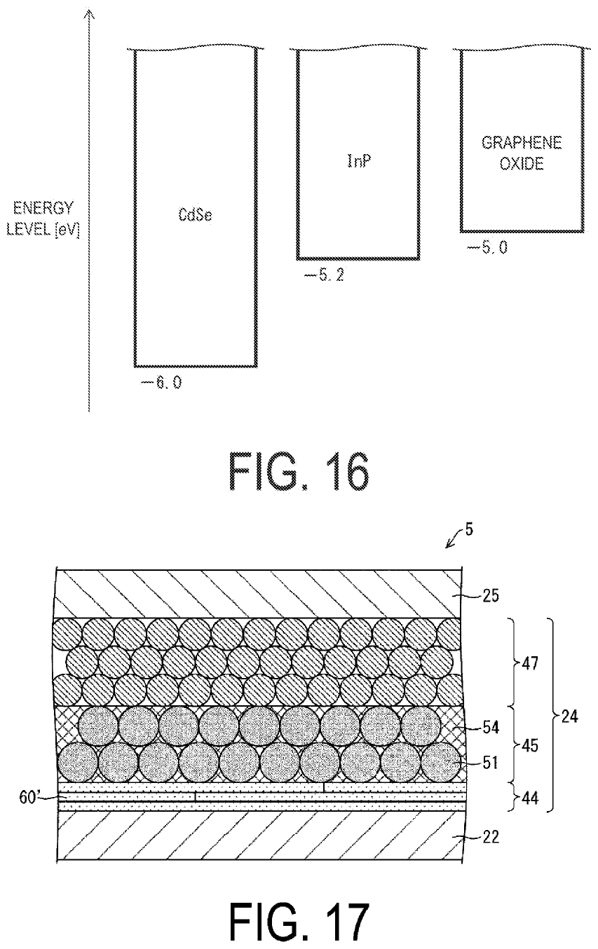

FIG. 16 is a diagram illustrating an example of energy levels of highest occupied molecular orbitals (HOMOs) of a quantum dot composed of CdSe and ZnS, a quantum dot composed of InP and ZnS, and graphene oxide. Note that in FIGS. 16, 26, and 31, for convenience, an energy level of the HOMO of a core (CdSe) in a core-shell structure is shown as the energy level of the HOMO of the quantum dot composed of CdSe and ZnS and an energy level of the HOMO of a core (InP) in a core-shell structure is shown as the energy level of the HOMO of the quantum dot composed of InP and ZnS.

As shown in FIG. 16, the HOMO of the quantum dot composed of InP and ZnS is shallower than the HOMO of the quantum dot composed of CdSe and ZnS and slightly deeper than the HOMO of graphene oxide. Due to this, the In-based quantum dot has a hole injection barrier smaller than that of the Cd-based quantum dot. Thus, the hole injection efficiency from graphene oxide is higher in the In-based quantum dot than in the Cd-based quantum dot.

Accordingly, preferably, the quantum dots 51 are InP-based quantum dots using quantum dots composed of InP and ZnS in the core 52, the anode-side platelet layer 44 functions as the hole transport layer, and the nanoplatelets 60′ constituting the anode-side platelet layer 44 are nanoplatelets containing graphene oxide. The quantum dots composed of InP and ZnS have a core-shell structure in which nanocrystals of InP are included and the periphery of the nanocrystals of InP is coated with ZnS.

### Second Embodiment

Hereinafter, an embodiment of the present invention will be described in detail with reference to the drawings. Note that, for convenience of description, members having the same functions as those of the members described in the above-described embodiment will be denoted by the same reference numerals and signs, and the description thereof will not be repeated.

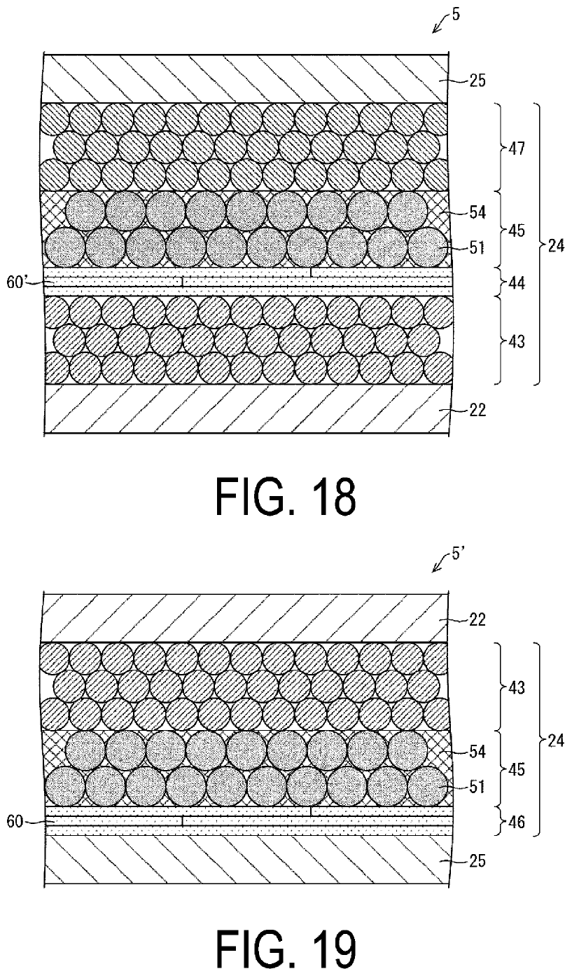

FIG. 17 is a cross-sectional view illustrating an example of a schematic configuration of a light-emitting element layer 5 according to the present embodiment. FIG. 18 is a cross-sectional view illustrating another example of the schematic configuration of the light-emitting element layer 5 according to the present embodiment.

As illustrated in FIG. 17 and FIG. 18, an active layer 24 of the light-emitting element layer 5 according to the present embodiment includes, for example, an anode-side platelet layer 44, a light-emitting layer 45, and a cathode-side coating layer 47 in this order. The active layer 24 may have an anode-side coating layer 43 formed in a lower layer below the anode-side platelet layer 44.

The anode-side platelet layer 44 is formed on an anode 22 or the anode-side coating layer 43, is formed in a lower layer below the light-emitting layer 45, and is adjacent to the light-emitting layer 45.

### Effect of Platelet Layer

In the prior art, when the light-emitting layer 45 is formed directly on the anode 22 or the anode-side coating layer 43, the light-emitting layer 45 receives an effect of irregularities of the upper face of the anode 22 or the anode-side coating layer 43. In particular, if there is a foreign matter on the upper face, unevenness tends to occur in the film thickness of the light-emitting layer 45. Thus, in the prior art, the boundary between the light-emitting layer 45 and a lower adjacent layer thereof has irregularities. In contrast, in the configuration according to the present embodiment, the anode-side platelet layer 44 covers over the irregularities and the foreign matter on the upper face of the anode 22 or the anode-side coating layer 43. Accordingly, the boundary between the light-emitting layer 45 and the anode-side platelet layer 44 has less irregularities and is clear, as compared to the prior art.

As in the first embodiment described above, a nanoplatelet 60′ according to the present embodiment preferably has a diameter R_plate larger than the diameter R_whole of each of quantum dots 51, more preferably larger than twice the diameter R_whole, and even more preferably larger than four times the diameter R_whole. Preferably, a width W_plate is larger than ½ times the diameter R_whole. A ratio of the diameter R_plate to a thickness T_plate is preferably larger than 1, more preferably larger than 2, even more preferably larger than 4, and still even more preferably larger than 8. The diameter R_plate is preferably larger than a film thickness D of the light-emitting layer 45. The thickness T_plate is preferably smaller than the diameter R_plate of each of the quantum dots, and specifically, the thickness T-plate is preferably the thickness of a single molecule layer constituting the nanoplatelet 60′ itself' or more and 5 nm or less. The size of a single molecule or smaller cannot be prepared, and thus the thickness is preferably 0.1 nm or more.

### First Modified Example

The anode 22, the cathode 25, and the active layer 24 therebetween may be formed in a reverse order.

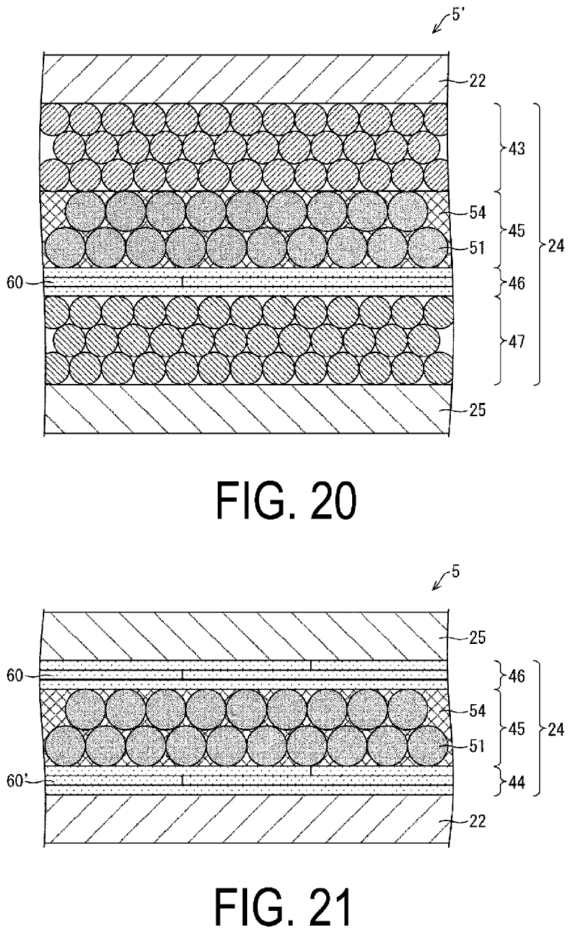

FIG. 19 is a cross-sectional view illustrating an example of a schematic configuration of a light-emitting element layer 5′ according to a modified example of the present embodiment. FIG. 20 is a cross-sectional view illustrating another example of the schematic configuration of the light-emitting element layer 5′ according to the modified example of the present embodiment.

As illustrated in FIG. 19 and FIG. 20, in the light-emitting element layer 5′ according to the present modified example, the active layer 24 is formed in an upper layer above the cathode 25, and the anode 22 is formed in an upper layer above the active layer 24. The active layer 24 according to the present modified example includes, for example, the cathode-side platelet layer 46, the light-emitting layer 45, and the anode-side coating layer 43 in this order. The active layer 24 may have a cathode-side coating layer 47 formed in a lower layer below the cathode-side platelet layer 46.

As in the first embodiment described above, the nanoplatelet 60 according to the present embodiment preferably has a diameter R_plate larger than the diameter Rwhole of each of the quantum dots 51, more preferably larger than twice the diameter R and even more preferably larger than four times the diameter R_whole. Preferably, a width W_plate is larger than ½ times the diameter R_whole. A ratio of the diameter R_plate to a thickness T_plate is preferably larger than 1, more preferably larger than 2, even more preferably larger than 4, and still even more preferably larger than 8. The diameter R_plate is preferably larger than a film thickness D of the light-emitting layer 45. The thickness T_plate is preferably smaller than the diameter R_plate of each of the quantum dots, and specifically, the thickness T_plate is preferably the thickness of a single molecule layer constituting the nanoplatelet 60′ itself or more and 5 nm or less. The size of a single molecule or smaller cannot be prepared, and thus the thickness is preferably 0.1 nm or more.

### Second Modified Example

Furthermore, in combination with the configuration according to the first embodiment described above, a platelet layer may be provided below and above the light-emitting layer 45.

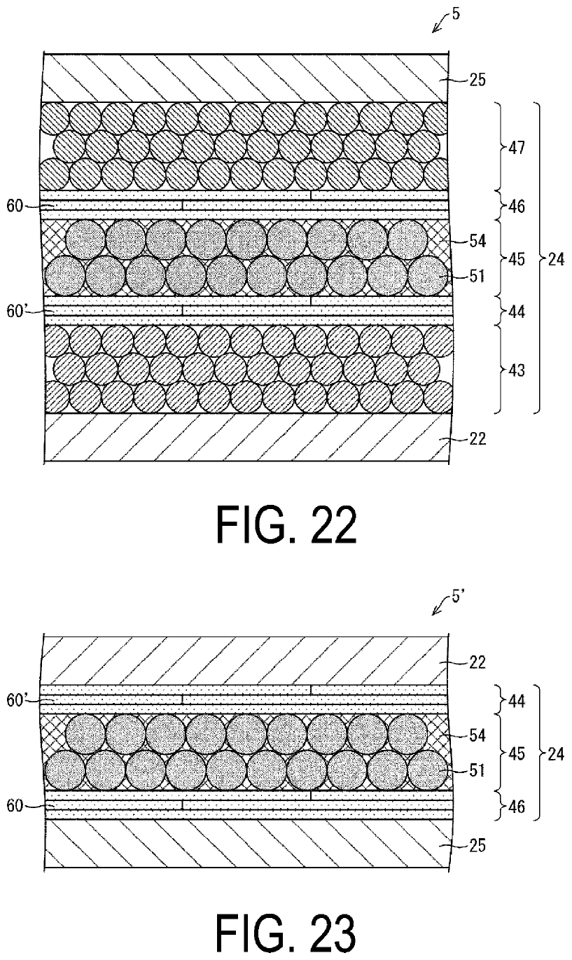

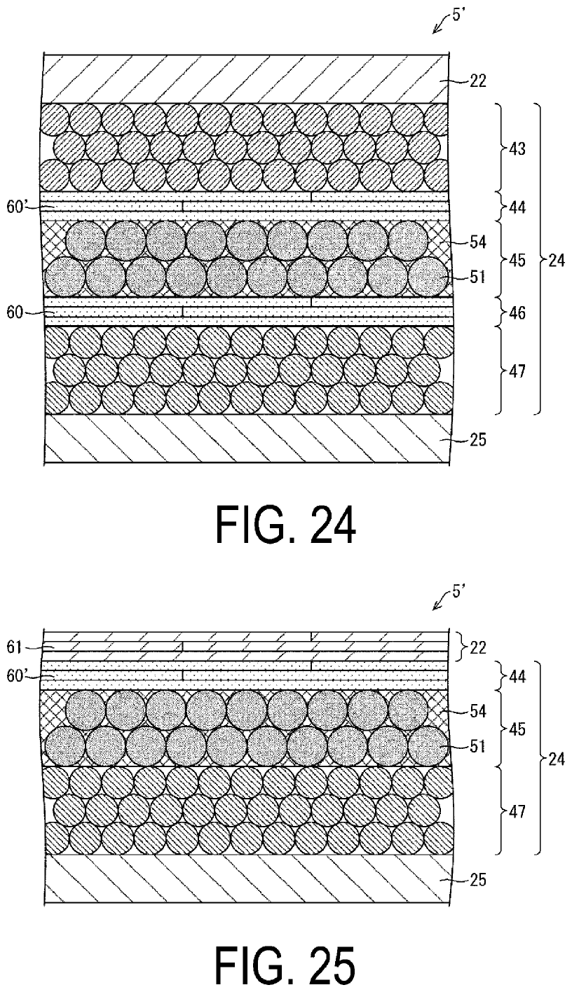

FIG. 21 is a cross-sectional view illustrating an example of a schematic configuration of a light-emitting element layer 5 according to a modified example of the present embodiment. FIG. 22 is a cross-sectional view illustrating another example of the schematic configuration of the light-emitting element layer 5 according to the modified example of the present embodiment. FIG. 23 is a cross-sectional view illustrating an example of a schematic configuration of a light-emitting element layer 5′ according to a modified example of the present embodiment. FIG. 24 is a cross-sectional view illustrating another example of the schematic configuration of the light-emitting element layer 5′ according to the modified example of the present embodiment.

As illustrated in FIG. 21 and FIG. 22, there may be provided a platelet layer having two layers, that is, an anode-side platelet layer 44 and a cathode-side platelet layer 46. The anode-side platelet layer 44, which is one of the two layers, is a lower layer below the light-emitting layer 45 and is adjacent to the light-emitting layer 45. The cathode-side platelet layer 46, which is the other of the two layers, is an upper layer above the light-emitting layer 45 and is adjacent to the light-emitting layer 45.

As illustrated in FIG. 23 and FIG. 24, there may be provided a platelet layer having two layers, that is, an anode-side platelet layer 44 and a cathode-side platelet layer 46. The anode-side platelet layer 44, which is one of the two layers, is an upper layer above the light-emitting layer 45 and is adjacent to the light-emitting layer 45. The cathode-side platelet layer 46, which is the other of the two layers, is a lower layer below the light-emitting layer 45 and is adjacent to the light-emitting layer 45.

### Third Embodiment

Hereinafter, an embodiment of the present invention will be described in detail with reference to the drawings. Note that, for convenience of description, members having the same functions as those of the members described in the above-described embodiment will be denoted by the same reference numerals and signs, and the description thereof will not be repeated.

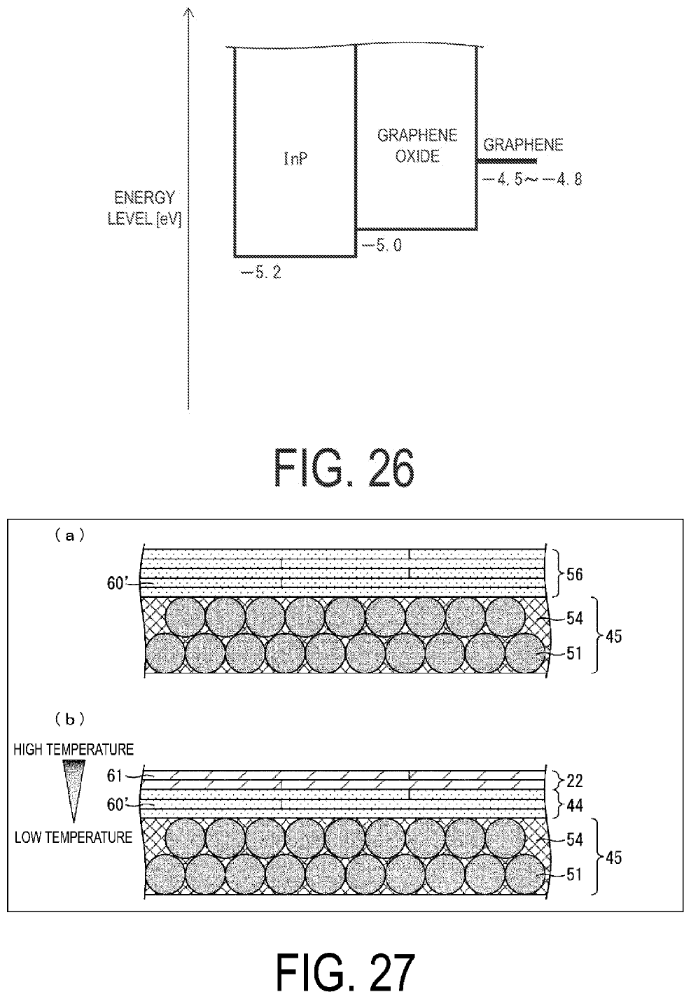

FIG. 25 is a cross-sectional view illustrating an example of a schematic configuration of a light-emitting element layer 5′ according to the present embodiment. FIG. 26 is a diagram illustrating an example of energy levels of HOMOs of a quantum dot composed of InP and ZnS, graphene oxide, and graphene.

As illustrated in FIG. 25, a cathode 25, an active layer 24, and an anode 22 are layered in this order on the light-emitting element layer 5′ according to the present embodiment. A cathode-side coating layer 47, a light-emitting layer 45, and an anode-side platelet layer 44 are layered in this order on the active layer 24 according to the present embodiment. The anode 22 is composed of nanoplatelets 61 and is adjacent to the anode-side platelet layer 44.

In the present embodiment, nanoplatelets 60′ of the anode-side platelet layer 44 are nanoplatelets of graphene oxide and the nanoplatelets 61 of the anode 22 are nanoplatelets of graphene. Due to this, when quantum dots 51 are in-based, holes in the quantum dots 51, the anode-side platelet layer 44, and the anode 22 have energy levels illustrated in FIG. 26. Thus, the hole injection efficiency from the anode 22 to the quantum dots 51 is high. The anode 22 is a transparent electrode formed from a material containing graphene.

### Manufacturing Method

Several examples of methods in which the anode-side platelet layer 44 and the anode 22 according to the present embodiment can be manufactured will be described below with reference to FIG. 27 to FIG. 29.

FIG. 27 to FIG. 29 are cross-sectional views each illustrating an example of a method in which the anode-side platelet layer 44 and the anode 22 according to the present embodiment can be manufactured.

As an example, as illustrated in (a) of FIG. 27, a solution containing the nanoplatelets 60′ is applied onto the light-emitting layer 45 and a solvent is volatilized to form a deposited layer 56. Subsequently, as illustrated in (b) of FIG. 27, in a reduced atmosphere, only an upper portion of the deposited layer 56 is heated to reduce the nanoplatelets 60′ of graphene oxide to the nanoplatelets 61 of graphene only in the upper portion of the deposited layer 56. As a method for heating only the upper portion of the deposited layer 56, for example, a method of putting a substrate on which the deposited layer 56 is formed in an oven with a temperature gradient, or a method of irradiating the upper face of the deposited layer 56 with hot air or light for a short period of time or in a pulsed manner may be used. In this method, of the deposited layer 56, a non-reduced lower portion becomes the anode-side platelet layer 44 and the reduced upper portion becomes the anode 22. In this method, a step of forming the anode-side platelet layer 44 and a step of forming the anode 22 are shared, so that a step of forming the light-emitting element layer 5′ is simplified.

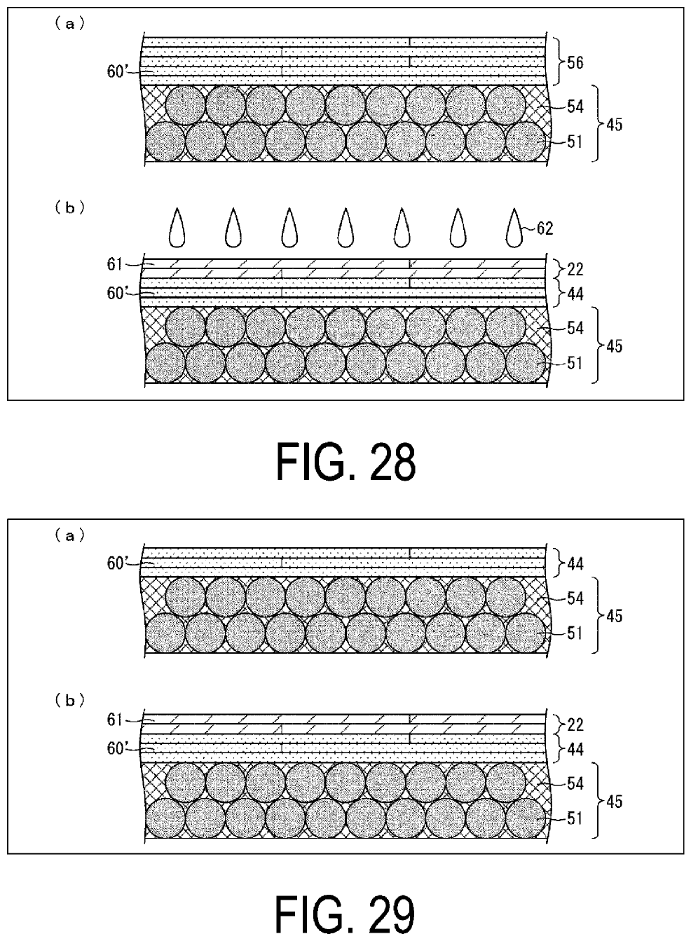

As another example, as illustrated in (a) of FIG. 28, a solution containing the nanoplatelets 60′ is applied onto the light-emitting layer 45 and a solvent is volatilized to form the deposited layer 56. Subsequently, as illustrated in (b) of FIG. 28, a solution 62 containing a reducing agent is sprayed to reduce the nanoplatelets 60′ of graphene oxide to the nanoplatelets 61 of graphene only in an upper portion of the deposited layer 56. Alternatively, a reducing gas such as hydrogen gas may be sprayed. In this method, of the deposited layer 56, a non-reduced lower portion becomes the anode-side platelet layer 44 and the reduced upper portion becomes the anode 22. In this method, a step of forming the anode-side platelet layer 44 and a step of forming the anode 22 are shared, so that a step of forming the light-emitting element layer 5′ is simplified.

As yet another example, as illustrated in (a) of FIG. 29, a solution containing nanoplatelets 60′ is applied onto the light-emitting layer 45 and a solvent is volatilized to form the anode-side platelet layer 44. A solution containing nanoplatelets 61 is then applied onto the anode-side platelet layer 44 and a solvent is volatilized to form the anode 22. In this method, a step of forming the anode-side platelet layer 44 and a step of forming the anode 22 are separated, so that film thicknesses of the anode-side platelet layer 44 and the anode 22 are easily adjusted individually.

### Modified Example

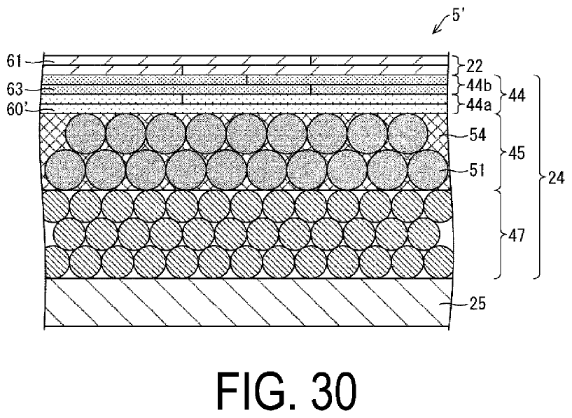

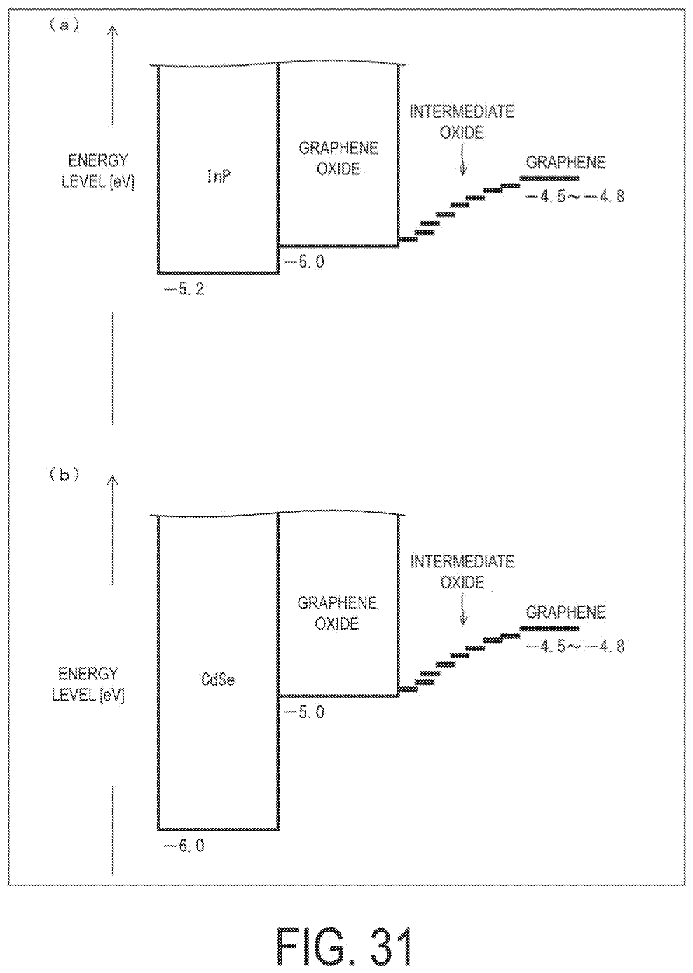

FIG. 30 is a diagram illustrating another example of the schematic configuration of the light-emitting element layer 5′ according to the present embodiment. (a) of FIG. 31 is a diagram illustrating an example of energy levels of HOMOs of a quantum dot composed of InP and ZnS, graphene oxide, an intermediate oxide between graph.ene oxide and graphene, and graphene, (b) of FIG. 31 is a diagram illustrating an example of energy levels of HOMOs of a quantum dot composed of CdSe and ZnS, graphene oxide, an intermediate oxide between graphene oxide and graphene, and graphene. The intermediate oxide between graphene oxide and graphene is also referred to as reduced graphene oxide (rGO).

As illustrated in FIG. 30, the anode-side platelet layer 44 may include an oxide layer 44a composed of the nanoplatelets 60′ of graphene oxide and an intermediate oxide layer 44b composed ofnanoplatelets 63 of an intermediate oxide between graphene oxide and graphene. In the intermediate oxide layer 44b, the nanoplatelets 63 of the intermediate oxide have a higher oxidation degree on the oxide layer 44a side and a higher reduction degree on the anode 22 side. In other words, the anode-side platelet layer 44 has a composition inclined from graphene oxide to graphene toward the anode 22 side from the light-emitting layer 45 side. The nanoplatelets 63 of the intermediate oxide are those in which the nanoplatelets 60′ of graphene oxide have been reduced incompletely.

The intermediate oxide layer 44b can be formed, for example, by adjusting the reduction of the deposited layer 56 in the method illustrated in FIG. 27 or FIG. 28 such that there is an intermediate portion in which some of the nanoplatelets 60′ of graphene oxide are reduced, between the lower portion which is not reduced at all and the upper portion that is completely reduced.

As illustrated in FIG. 31, in the light-emitting element layer 5′ according to the present embodiment, the HOMO of the intermediate oxide in the intermediate oxide layer 44b of the anode-side platelet layer 44 connects the HOMO of graphene oxide in the oxide layer 44a of the anode-side platelet layer 44 and the HOMO of graphene in the anode 22 in a step-like manner. As a result, the injection barrier of holes from the anode 22 to the oxide layer 44a becomes step-shaped, so that the injection efficiency of holes is improved.

### Fourth Embodiment

Hereinafter, an embodiment of the present invention will be described in detail with reference to the drawings. Note that, for convenience of description, members having the same functions as those of the members described in the above-described embodiment will be denoted by the same reference numerals and signs, and the description thereof will not be repeated.

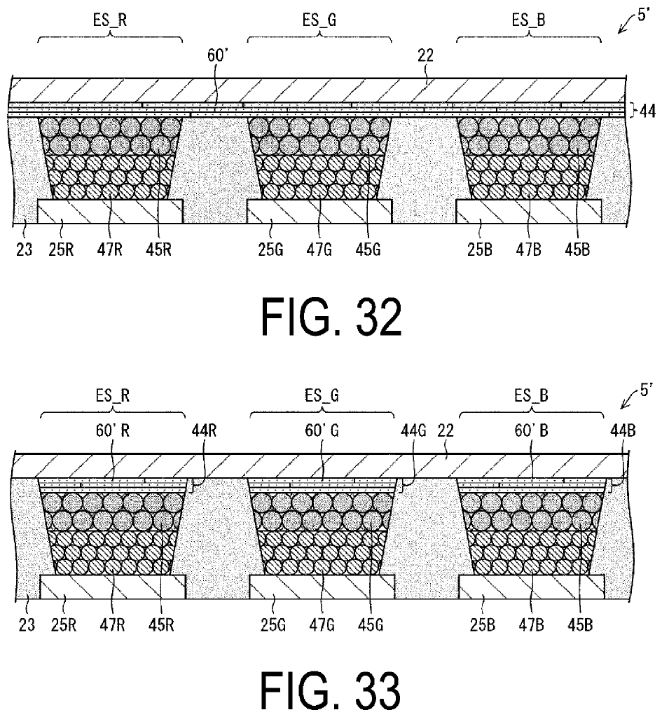

FIG. 32 is a diagram illustrating an example of a schematic configuration of a light-emitting element layer 5′ according to the present embodiment. The light-emitting element layer 5′ according to the present embodiment is included in a display device that can display red-blue-green three primary colors. In the light-emitting element layer 5′, a red light-emitting element ES_R as a red pixel, a blue light-emitting element ES_B as a blue pixel, and a green light-emitting element ES_G as a green pixel are formed.

In the red light-emitting element ES_R, a red cathode-side coating layer 47R, a red light-emitting layer 45R, an anode-side platelet layer 44, and an anode 22 are layered in an upper layer above a red cathode 25R. In the green light-emitting element ES_G, a green cathode-side coating layer 47G, a green light-emitting layer 45G, the anode-side platelet layer 44, and the anode 22 are layered in an upper layer above a green cathode 25G. In the blue light-emitting element ES_B, a blue cathode-side coating layer 47B, a blue light-emitting layer 45B, the anode-side platelet layer 44, and the anode 22 are layered in an upper layer above a blue cathode 25B. The anode-side platelet layer 44 and the anode 22 are formed on the entire surface of a display region, and are common to the light-emitting elements ES_R, ES_B, and ES_G of the respective colors.

Because the anode-side platelet layer 44 is common, the nanoplatelets 60′ constituting the anode-side platelet layer 44 preferably satisfy the conditions described in the above-described first to third embodiments with respect to the light-emitting layers 45R, 45B, and 45G of the respective colors. Usually, the largest quantum dot is included in the red light-emitting layer 45R among the light-emitting elements ES_R, ES_B, and ES_G of the respective colors. A film thickness of the light-emitting layer is typically proportional to the diameter R_whole of each of included quantum dots. Accordingly, the nanoplatelets 60 constituting the cathode-side platelet layer 46 preferably satisfy the conditions described in the above-described first to third embodiments with respect to the red light-emitting layer 45R.

Specifically, the nanoplatelets 60′ constituting the anode-side platelet layer 44 each preferably have a diameter R_plate larger than the diameter R_whole of each of the quantum dots included in the red light-emitting layer 45R, more preferably larger than twice the diameter R_whole, and even more preferably larger than four times the diameter R_whole. The width W plate is preferably larger than ½ times the diameter R_whole of each of the quantum dots included in the red light-emitting layer 45R. A ratio of the diameter R_plate of the nanoplatelet 60 to the thickness T_plate of the nanoplatelet 60 is preferably larger than 1, more preferably larger than 2, even more preferably larger than 4, and even more preferably larger than 8. The diameter R_plate of the nanoplatelet 60 is preferably larger than the film thickness D of the red light-emitting layer 45R. The thickness T_plate of the nanoplatelet 60 is preferably smaller than the diameter R_plate of each of the quantum dots included in the red light-emitting layer 45R, and is preferably the thickness of a single molecule layer constituting the nanoplatelet 60 itself or more and 5 nm or less. The size of a single molecule or smaller cannot be prepared, and thus the thickness is preferably 0.1 nm or more.

### Fifth Embodiment

Hereinafter, an embodiment of the present invention will be described in detail with reference to the drawings. Note that, for convenience of description, members having the same functions as those of the members described in the above-described embodiment will be denoted by the same reference numerals and signs, and the description thereof will not be repeated.

FIG. 33 is a diagram illustrating an example of a schematic configuration of a light-emitting element layer 5′ according to the present embodiment. The light-emitting element layer 5′ according to the present embodiment is included in a display device that can display red-blue-green three primary colors. In the light-emitting element layer 5′, a red light-emitting element ES_R, a blue light-emitting element ES_B, and a green light-emitting element ES_G are formed.

In the red light-emitting element ES_R, a red cathode-side coating layer 47R, a red light-emitting layer 45R, a red anode-side platelet layer 44R, and an anode 22 are layered in an upper layer above a red cathode 25R. In the green light-emitting element ES_G, a green cathode-side coating layer 47G, a green light-emitting layer 45G, a green anode-side platelet layer 44G, and the anode 22 are layered in an upper layer above a green cathode 25G. In the blue light-emitting element ES_B, a blue cathode-side coating layer 47B, a blue light-emitting layer 45B, a blue anode-side platelet layer 44B, and the anode 22 are layered in an upper layer above a blue cathode 25B. The anode-side platelet layers 44R, 44G, and 44B of the respective colors are individually formed for the light-emitting elements ES_R, ES_G, and ES_B, respectively. The anode 22 is formed on the entire surface of a display region, and is common to the tight-emitting elements ES_R, ES_B, and ES_G of the respective colors.

The anode-side platelet layers 44R, 44G, and 44B are individually formed, and thus nanoplatelets 60′R, 60′G, and 60′B constituting the anode-side platelet layers 44R, 44G, and 44B of the respective colors can differ from each other in diameter R_plate. In addition, the nanoplatelets 60′R, 60′G, and 60′B can differ from each other in ratio of the diameter R_plate to the thickness T_plate.

The nanoplatelets 60′R, 60′G, and 60′B of the respective colors preferably satisfy the conditions described in the above-described first to third embodiments with respect to the light-emitting layers 45R, 45B, and 45G of the corresponding colors. When core materials of quantum dots are the same, the largest quantum dot is typically included in the red light-emitting layer 45R among the light-emitting elements ES_R, ES_B, and ES_G of the respective colors. Accordingly, preferably, the diameter R_plate of the nanoplatelet 60′R in the red anode-side platelet layer 44R is largest, and the diameter R_plate of the nanoplatelet 60′13 in the blue anode-side platelet layer 44B is smallest. In addition, when the thicknesses T_plate of the nanoplatelets 60′R, 60′G, and 60′B are substantially the same, preferably, the ratio of the diameter R_plate; to the thickness T_plate is largest in the nanoplatelet 60′R in the red anode-side platelet layer 44R and is smallest in the nanoplatelet 60′B in the blue anode-side platelet layer 44B.

The nanoplatelets 60′R, 60′G, and 60′B are individually formed and thus may differ from each other in composition. Typically, HOMOs and LUMOs of the quantum dots of the respective colors are different from each other. The injection barrier of charges may be made uniform to select the nanoplatelets 60′R, 60′G, and 60′B so as to conform to the HOMO of the quantum dot of the corresponding color for making the charge injection efficiency uniform. For example, the nanoplatelets 60′R, 60′G, and 60′B each may be a reduction product of graphene oxide to conform to the HOMO of the quantum dot of the corresponding color. In this case, the nanoplatelets 60′R, 60′G, and 60′B each are one or a mixture of two or more of graphene oxide, graphene, and an intermediate oxide between graphene oxide and graphene, and differ from each other in composition ratio. For example, for the nanoplatelets 60′R, 60′G, and 60′B, an organic material having appropriate HOMO and LUMO may be used to conform to the HOMO of the quantum dots of the corresponding colors. For example, for the nanoplatelets 60′R, 60′G, and 60′B, an inorganic material such as graphene oxide and nickel oxide having appropriate HOMO and LUMO may be used to conform to the HOMO of the quantum dots of the corresponding colors.

The anode-side platelet layers 44R, 44G, and 44B are individually formed and thus may differ from each other in layer thickness. For example, when the quantum dots of the respective colors are In-based, the HOMO is deepest in the red quantum dot and shallowest in the blue quantum dot. Accordingly, in order to make the hole injection efficiency uniform for the light-emitting elements ES_R, ES_B, and ES_G of the respective colors, it is preferable to form the anode-side platelet layers 44R, 44G, and 44B such that the layer thickness of the red anode-side platelet layer 44R is largest and the layer thickness of the blue anode-side platelet layer 44B is smallest.

The anode-side platelet layers 44R, 44G, and 44B are layered films in which the nanoplatelets 60′R, 60′G, and 60′B are layered, respectively. Thus, it can be said that the numbers of layers of the nanoplatelets 60′R, 60′G, and 60′B in the anode-side platelet layers 44R, 44G, and 44B of the respective colors may be different from each other. It can also be said that preferably, the number of layers of the nanoplatelets 60′R in the red anode-side platelet layer 44R is largest and the number of layers of the nanoplatelets 60′B in the blue anode-side platelet layer 44B is smallest.

### REFERENCE SIGNS LIST

2 Display device (display device)

22 Anode (anode electrode)

25, 25R, 25G, 25B Cathode (cathode electrode)

44, 44R, 44G, 44B Anode-side platelet layer (platelet layer)

45 Light-emitting layer

45B Blue light-emitting layer (light-emitting layer)

45G Green light-emitting layer (light-emitting layer)

45R Red light-emitting layer (light-emitting layer)

46 Cathode-side platelet layer (platelet layer)

51 Quantum dot

52 Core

53 Modifying group

60, 60a to 60n, 60′ Nanoplatelet

T_plate Thickness of nanoplatelet

W_plate Width of nanoplatelet

R_plate Diameter of nanoplatelet

R_whole Diameter of quantum dot

ES Light-emitting element (electroluminescence element)

ES_R Light-emitting element (electroluminescence element, red pixel)

ES_G Light-emitting element (electroluminescence element, green pixel)

ES_B Light-emitting element (electroluminescence element, blue pixel)

1. A display device comprising:
an electroluminescence element,
wherein the electroluminescence element comprising:
a cathode electrode and an anode electrode being paired; and
a light-emitting layer disposed between the cathode electrode and the anode electrode, the light-emitting layer including quantum dots, wherein the electroluminescence element further comprises a platelet layer adjacent to the light-emitting layer, the platelet layer including nanoplatelets each having a plate shape, and
wherein a diameter of each of the nanoplatelets is greater than a diameter of each of the quantum dots.

2-4. (canceled)

5. The display device according to claim 1,
wherein a width of each of the nanoplatelets is larger than ½ times the diameter of each of the nanoplatelets.

6. (canceled)

7. The display device according to claim 1,
wherein a ratio of the diameter to a thickness of each of the nanoplatelets is larger than 2.

8-10. (canceled)

11. The display device according to any claim 1,
wherein a thickness of each of the nanoplatelets is a thickness of a single molecule layer constituting each of the nanoplatelets or more and 5 nm or less.

12. The display device according to claim 1,
wherein the platelet layer is an upper layer above the light-emitting layer.

13. The display device according to claim 1,
wherein the platelet layer is a lower layer below the light-emitting layer.

14. The display device according to claim 1,
wherein the platelet layer has two layers,
one of the two layers is an upper layer above the light-emitting layer, and
the other of the two layers is a lower layer below the light-emitting layer.

15. The display device according to claim 1,
wherein the platelet layer functions as at least one of a charge blocking layer, a charge transport layer, and a charge injection layer.

16. The display device according to claim 1,
wherein each of the nanoplatelets includes 50% or more and 100% or less of an organic matter, and
wherein each of the nanoplatelets includes 99% or more and 100% or less of the organic matter.

17. (canceled)

18. The display device according to claim 16,
wherein each of the nanoplatelets comprises the organic matter, and
wherein the organic matter is a semiconductor.

19. (canceled)

20. The display device according to claim 16,
wherein the organic matter includes at least one compound selected from a triarylamine-based compound, a fused polycyclic hydrocarbon, and a fused heterocyclic compound, and
wherein the organic matter includes at least one compound selected from NPB (N,N′-bis(2-naphthyl)-N,N′-diphenylbenzidine), TPD (N,N′-bis(3-methylphenyl)-N,N′-bisphenylbenzidine), tetracene, perylene, and CBP (4,4′-bis(N-carbazolyl)biphenyl).

21. (canceled)

22. The display device according to claim 1,
wherein each of the nanoplatelets includes 50% or more and 100% or less of an inorganic matter, and
wherein each of the nanoplatelets includes 99% or more and 100% or less of the inorganic matter.

23. (canceled)

24. The display device according to claim 22,
wherein each of the nanoplatelets comprises the inorganic matter, and
wherein the inorganic matter is a semiconductor.

25. (canceled)

26. The display device according to claim 22,
wherein the inorganic matter includes at least one compound selected from graphene oxide, graphene, and an intermediate oxide between graphene oxide and graphene.

27. The display device according to claim 1,
wherein the quantum dots include nanocrystals of InP,
the platelet layer functions as a hole transport layer, and
each of the nanoplatelets includes graphene oxide, and
wherein each of the quantum dots comprises a core and a modifying group that modifies a surface of the core, and
a diameter of each of the quantum dots is a diameter including the modifying group.

28. The display device according to claim 1,
wherein the anode electrode is a reflective electrode configured to reflect light emitted by the light-emitting layer, and
the cathode electrode is a transparent electrode configured to transmit light emitted by the light-emitting layer,
wherein the reflective electrode is formed from a material containing Al or Ag, and
the transparent electrode is formed from a material containing Ag, and
wherein the transparent electrode is formed from a material containing graphene.

29. The display device according to claim 1,
wherein the anode electrode is a transparent electrode configured to transmit light emitted by the light-emitting layer, and
the cathode electrode is a reflective electrode configured to reflect light emitted by the light-emitting layer,
wherein the reflective electrode is formed from a material containing Al or Ag, and
the transparent electrode is formed from a material containing Ag, and
wherein the transparent electrode is formed from a material containing graphene.

31. (canceled)

32. The display device according to claim 16,
wherein the platelet layer has a composition inclined from graphene oxide to graphene toward the anode electrode side from a side of the light-emitting layer.

33. The display device according to claim 1,
wherein the platelet layer is a layered film in which the nanoplatelets are layered, and
wherein the light-emitting layer completely overlaps with the platelet layer.

34. (canceled)

38. The display device according to claim 1, comprising:
a red pixel;
a green pixel; and
a blue pixel,
wherein each of the red pixel, the green pixel, and the blue pixel includes the electroluminescence element.

39. The display device according to claim 38,
wherein the nanoplatelets are common to the red pixel, the green pixel, and the blue pixel.

40. The display device according to claim 38,
wherein the nanoplatelets differ in composition among the red pixel, the green pixel, and the blue pixel.

41. The display device according to claim 40,
wherein the nanoplatelets are one or a mixture of two or more of graphene oxide, graphene, and an intermediate oxide between graphene oxide and graphene in any of the red pixel, the green pixel, and the blue pixel, and
the nanoplatelets have different composition ratios among the red pixel, the green pixel, and the blue pixel.

42. The display device according to claim 38,
wherein the platelet layer differs in layer thickness among the red pixel, the green pixel, and the blue pixel, and
wherein the platelet layer is a layered film in which the nanoplatelets are layered, and
the red pixel, the green pixel, and the blue pixel differ from each other in number of layers of the nanoplatelets.

43. The display device according to claim 42,
wherein a layer thickness of the platelet layer is largest in the red pixel and is smallest in the blue pixel, and
wherein the number of layers of the nanoplatelets is largest in the red pixel and smallest in the blue pixel.

44-45. (canceled)

46. The display device according to claim 38,
wherein the diameter of each of the nanoplatelets is different among the red pixel, the green pixel, and the blue pixel, and
wherein the diameter of each of the nanoplatelets is largest in the red pixel and smallest in the blue pixel.

47. (canceled)

48. The display device according to claim 38,
wherein a ratio of the diameter to a thickness of each of the nanoplatelets is different among the red pixel, the green pixel, and the blue pixel, and
wherein the ratio of the diameter to the thickness of each of the nanoplatelets is largest in the red pixel and smallest in the blue pixel.

49. (canceled)
